(19) United States
(12) Patent Application Publication
(10) Pub. No.: US 2025/0220888 A1
(43) Pub. Date: Jul. 3, 2025

(54) VERTICAL GATE-ALL-AROUND MEMORY DEVICE HAVING STACKED CAPACITOR STRUCTURE

(71) Applicant: Taiwan Semiconductor Manufacturing Company, Ltd., Hsin-Chu (TW)

(72) Inventors: Shih-Yu Liao, Hsinchu City (TW); Chung-Liang Cheng, Changhua County (TW)

(21) Appl. No.: 18/401,962

(22) Filed: Jan. 2, 2024

(51) Int. Cl. H10B 12/00; H01L 23/522; H01L 23/528; H01L 29/423; H01L 29/786; H10B 51/30; H10B 53/30

(52) U.S. Cl. CPC H10B 12/377; H01L 23/5226; H01L 23/5283; H10B 12/038; H10B 12/482; H10B 12/485; H10B 12/488; H10B 51/30; H10B 53/30; H10D 30/6735; H10D 30/6755; H10D 30/6757

(57) ABSTRACT

One aspect of the present disclosure pertains to a memory device. The memory device includes a semiconductor feature made of a compound semiconductor material. The semiconductor features includes a first portion as a first source/drain (S/D) feature, a second portion as a channel, and a third portion as a second S/D feature. The first portion is above the second portion and the second portion is above the third portion, and the second portion vertically extends from the first portion to the third portion. The memory device includes a gate structure horizontally wrapping around the second portion and a capacitor structure in direct contact with and wrapping around the semiconductor feature.

### BACKGROUND

The electronics industry has experienced an ever-increasing demand for smaller and faster electronic devices that are simultaneously able to support a greater number of increasingly complex and sophisticated functions. To meet these demands, there is a continuing trend in the integrated circuit (IC) industry to manufacture low-cost, high-performance, and low-power ICs. Thus far, these goals have been achieved in large part by reducing IC dimensions (for example, minimum IC feature size), thereby improving production efficiency and lowering associated costs. However, such scaling has also increased complexity of the IC manufacturing processes. Thus, realizing continued advances in IC devices and their performance requires similar advances in IC manufacturing processes and technology.

Many of the technological advances have occurred in the field of memory devices, which include 1-transistor 1-capacitor (1T1C) memory devices for dynamic random access memory (DRAM), ferroelectric RAM (FeRAM), and other types of memory. However, as more devices are integrated into a smaller area, integrating these 1T1C memory devices require improvements in device density. For example, many of the current 1T1C devices each include a planar transistor and a planar capacitor put on two separated metal layers. These 1T1C devices take up considerable space in the horizontal and vertical directions. Hence, device density cannot not further decrease.

Therefore, while existing methods and structures related to 1T1C memory devices are generally adequate for their intended purposes, they are not satisfactory in all aspects.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. It is also emphasized that the drawings appended illustrate only typical embodiments of this invention and are therefore not to be considered limiting in scope, for the invention may apply equally well to other embodiments.

FIG. 1A illustrates a circuit diagram of a memory device having a transistor and a capacitor, according to an embodiment of the present disclosure.

FIG. 1B illustrates a cross sectional-view of the memory device in FIG. 1A, according to an embodiment of the present disclosure.

FIGS. 2A-2B illustrate a flow chart of a method to form a memory device having a transistor and a capacitor, according to an embodiment of the present disclosure.

FIGS. 3-14 and 16-17 illustrate the formation of a memory device having a transistor and a capacitor at intermediate stages of fabrication and processed in accordance with the method of FIGS. 2A-2B, according to an embodiment of the present disclosure.

FIGS. 15A-1, 15A-2, and 15A-3 illustrate top views of the memory device in FIG. 14, cut along the lines A-A′, according to different embodiments of the present disclosure.

FIGS. 15B-1, 15B-2, and 15B-3 illustrate top views of the memory device in FIG. 14, cut along the lines B-B′, according to different embodiments of the present disclosure.

FIG. 18A illustrates a flow chart of a method to form an integrated circuit that includes the memory device in FIG. 1B, according to an embodiment of the present disclosure. FIG. 18B illustrates the integrated circuit formed by the method of FIG. 18A.

FIG. 19A illustrates a flow chart of a method to form an integrated circuit that includes the memory device in FIG. 1B, according to another embodiment of the present disclosure. FIG. 19B illustrates the integrated circuit formed by the method of FIG. 19A.

FIG. 20A illustrates a circuit diagram of a memory device having a transistor and a capacitor, according to an embodiment of the present disclosure.

FIG. 20B illustrates a cross sectional-view of the memory device in FIG. 20A, according to another embodiment of the present disclosure.

FIGS. 21A-21B illustrate a flow chart of a method to form a memory device having a transistor and a capacitor, according to another embodiment of the present disclosure.

FIGS. 22-41 and 43-44 illustrate the formation of a memory device having a transistor and a capacitor at intermediate stages of fabrication and processed in accordance with the method of FIGS. 21A-21B, according to an embodiment of the present disclosure.

FIGS. 42A-1, 42A-2, and 42A-3 illustrate top views of the memory device in FIG. 41, cut along the lines A-A′, according to different embodiments of the present disclosure.

FIGS. 42B-1, 42B-2, and 42B-3 illustrate top views of the memory device in FIG. 41, cut along the lines B-B′, according to different embodiments of the present disclosure.

FIG. 45A illustrates a flow chart of a method to form an integrated circuit that includes the memory device in FIG. 20B, according to an embodiment of the present disclosure. FIG. 45B illustrates the integrated circuit formed by the method of FIG. 45A.

FIG. 46A illustrates a flow chart of a method to form an integrated circuit that includes the memory device in FIG. 20B, according to another embodiment of the present disclosure. FIG. 46B illustrates the integrated circuit formed by the method of FIG. 46A.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Still further, when a number or a range of numbers is described with “about,” “approximately,” and the like, the term is intended to encompass numbers that are within a reasonable range including the number described, such as within +/−10% of the number described, or other values as understood by person skilled in the art. For example, the term “about 5 nm” may encompass the dimension range from 4.5 nm to 5.5 nm. And when comparing a dimension or size of a feature to another feature, the phrases “substantially the same,” “essentially the same,” “of similar size,” and the like, are understood to be within +/−10% between the compared features, or other values as understood by person skilled in the art. Further, disclosed dimensions of the different features can implicitly disclose dimension ratios between the different features.

The present disclosure relates to methods and structures directed to forming memory devices having a transistor vertically stacked with a capacitor structure. The transistor is a vertical gate-all-around (GAA) transistor having a channel horizontally wrapped by a gate, and the channel is vertically between a source and a drain. The capacitor structure is vertically stacked directly on a source or a drain of the transistor, thereby reducing passive device area and further increase device density. In one embodiment, the capacitor structure is vertically stacked above the transistor. In another embodiment, the capacitor structure is vertically stacked below the transistor. In either case, the memory device can be incorporated on a frontside or a backside of a larger semiconductor structure. For example, the memory device may be incorporated between metal lines in a frontside interconnect structure that is disposed over logic devices. For another example, the memory device may be incorporated on a backside of the logic devices and connected to a backside interconnect structure.

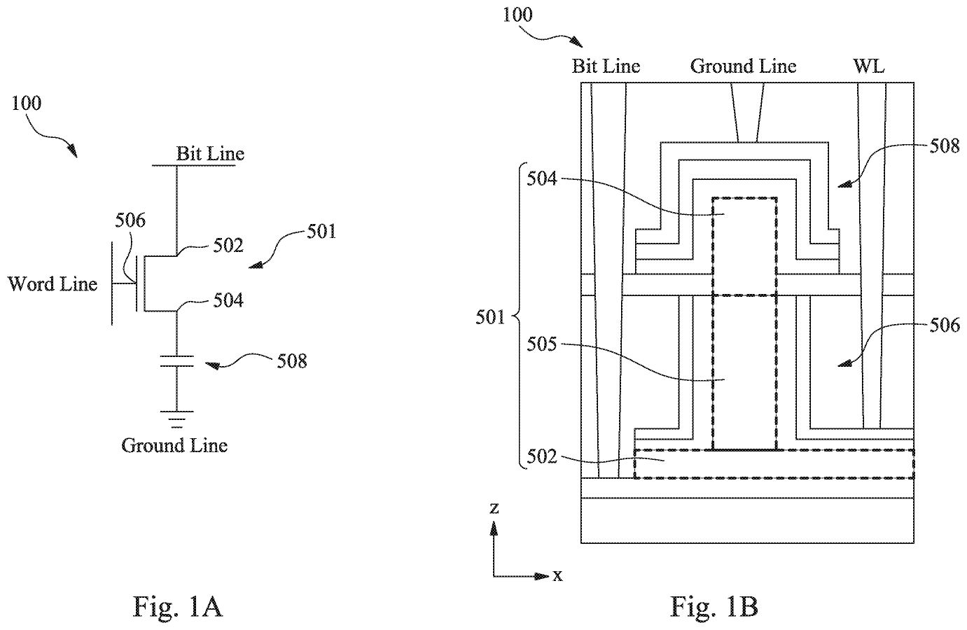

FIG. 1A illustrates a circuit diagram of a memory device 100 having a transistor 501 and a capacitor 508. The transistor 501 has a first terminal corresponding to a first source/drain (S/D) feature 502, a second terminal corresponding to a second S/D feature 504, and a third terminal corresponding to a gate 506. The gate 506 controls a channel between the first and second S/D features 502 and 504. The gate 506 is electrically connected to a word line of the memory device 100. The first S/D feature 502 (i.e., first terminal of transistor 501) is electrically connected to a bit line of the memory device 100, and the second S/D feature 504 (i.e., second terminal of transistor 501) is electrically connected to a capacitor 508, which is then electrically connected to a ground line. In an embodiment, the first S/D feature 502 corresponds to drain and the second S/D feature 504 corresponds to source. In this case, the drain of the transistor 501 is connected to a bit line, the source of the transistor 501 is connected to a first terminal (or electrode) of the capacitor 508, and a second terminal (or electrode) of the capacitor 508 is connected to a ground line. In another embodiment, the first S/D feature 502 corresponds to source and the second S/D feature 504 corresponds to drain. In this case, the source of the transistor 501 is connected to a bit line, the drain of the transistor 501 is connected to a first terminal (or electrode) of the capacitor 508, and a second terminal (or electrode) of the capacitor 508 is connected to a ground line. The bit line, word line, and ground line correspond to different connection nodes, and these nodes may be connected to other transistors 501 and other capacitors 508 in other memory devices 100. In an embodiment, the bit line, word line, and ground line are metal lines in a metal interconnect structure, and they connect to multiple memory devices 100 in a memory array.

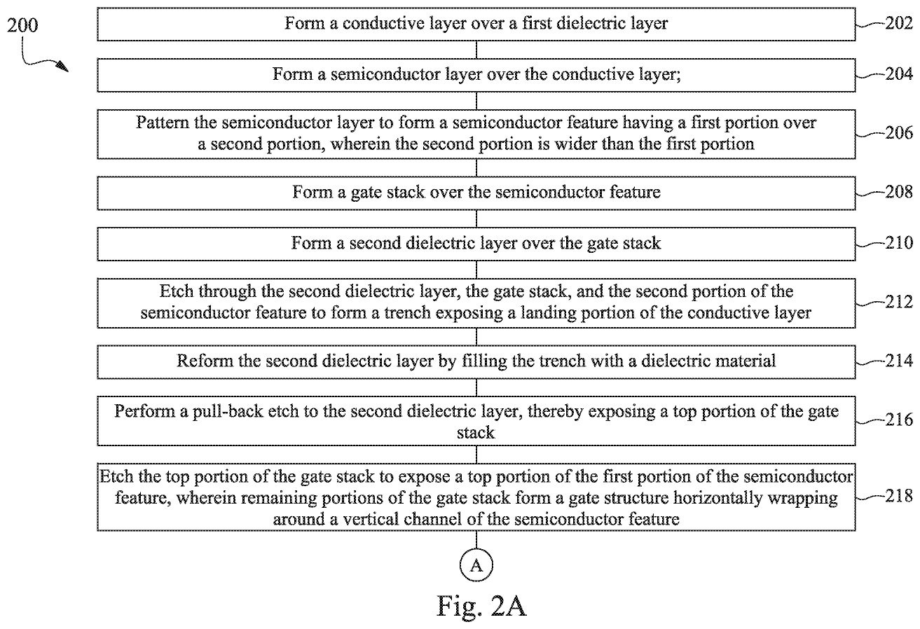

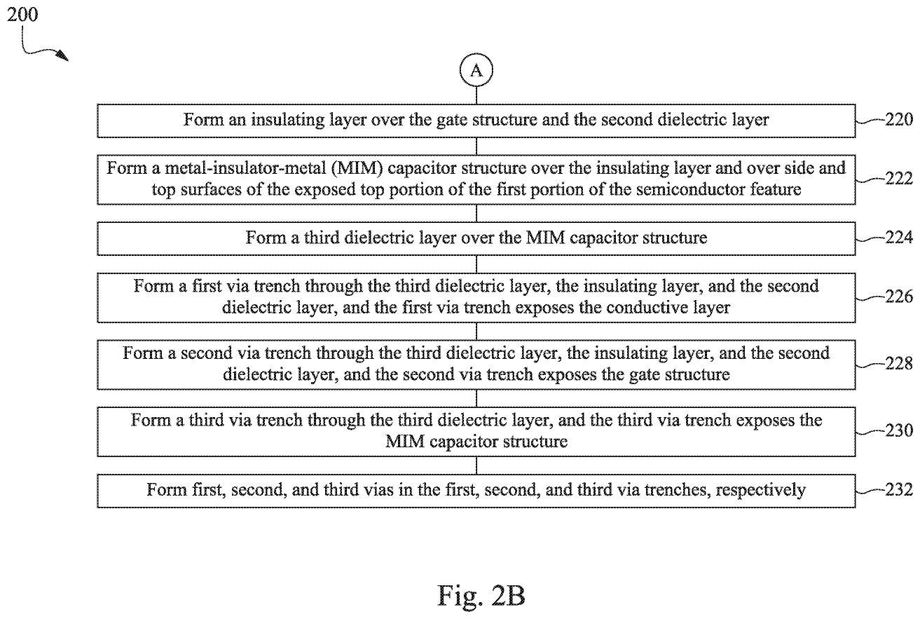

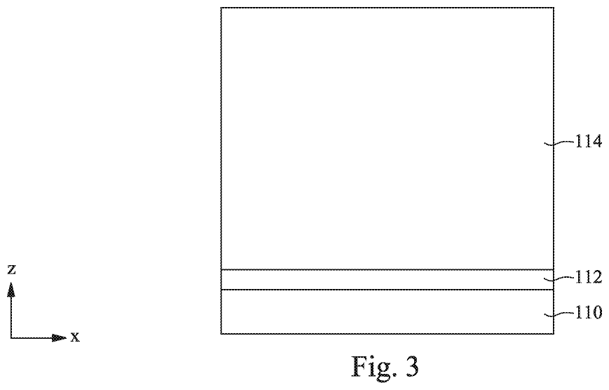

FIG. 1B illustrates a cross sectional-view of the memory device 100 in FIG. 1A, according to an embodiment of the present disclosure. Features described in FIG. 1A are similarly labeled in FIG. 1B. Note that there are additional features shown in FIG. 1B that will be described in more detail with respect to the method 200 in FIGS. 2A and 2B and the formation of the memory device 100 in FIGS. 3-14 and 16-17.

FIG. 1B shows a transistor 501 (also referred to as a semiconductor feature 501) having different portions that corresponds to source, drain, and channel. The semiconductor feature 501 may be made of a compound semiconductor material. In the embodiment shown, the compound semiconductor material includes indium gallium zinc oxide (IGZO). In other embodiments, the compound semiconductor material includes oxygen and at least two of the following three materials: indium, gallium, and zinc. In further embodiments, the semiconductor feature 501 may include hafnium oxide (HfO₂). In an embodiment, the semiconductor feature 501 is chosen to have high mobility in a polycrystalline or amorphous state. In other words, the semiconductor feature 501 does not have a crystalline structure but instead has an amorphous or polycrystalline structure. As such, the semiconductor feature 501 does not need to be formed on a semiconducting layer such as silicon but can be formed on a conductive layer such as titanium nitride.

Still referring to FIG. 1B, a gate 506 horizontally wraps around a vertical channel 505 of the semiconductor feature 501. In this cross-sectional view, the gate 506 is disposed on sidewalls of the channel 505. S/D features 502 and 504 of the semiconductor feature 501 are vertically above and below the channel 505. Described in another way, the semiconductor feature 501 includes a first portion (i.e., the second S/D feature 504) over a second portion (i.e., channel 505), and the second portion (i.e., channel 505) is over a third portion (i.e., first S/D feature 502). The second portion (i.e., channel 505) is vertically between and vertically extends from the first portion (i.e., the second S/D feature 504) to the third portion (i.e., first S/D feature 502). As shown, a capacitor 508 is in direct contact with and horizontally wrapping around the first portion (i.e., second S/D feature 504) of the semiconductor feature 501. In this case, the capacitor 508 is vertically stacked above the semiconductor feature 501. As will be described in more detail below, the first S/D feature 502 may be electrically connected to a bit line through a bit line via, the capacitor 508 may be electrically connected to a ground line through a ground line via, and the gate 506 may be electrically connected to a word line through a word line via.

FIGS. 2A-2B illustrate a flow chart of a method 200 to form a memory device 100 having a transistor 501 and a capacitor 508, according to an embodiment of the present disclosure. FIGS. 3-14 and 16-17 illustrate the formation of a memory device 100 at intermediate stages of fabrication and processed in accordance with the method 200 of FIGS. 2A-2B, according to an embodiment of the present disclosure. The method 200 is described below with reference to FIGS. 3-14 and 16-17.

Referring now to FIG. 3, the method 200 at operation 202 forms a conductive layer 112 over a dielectric layer 110 (or first dielectric layer 110). The dielectric layer 110 may be a base interlayer dielectric (ILD) layer from which the memory device 100 will be formed on. The dielectric layer 110 includes a dielectric material including, for example, silicon oxide, silicon nitride, silicon oxynitride, TEOS formed oxide, PSG, BPSG, low-k dielectric material, other suitable dielectric material, or combinations thereof. In an embodiment, the dielectric layer 110 includes silicon oxide or a low-k dielectric material. The conductive layer 112 may include a suitable conductive material such as titanium nitride. The conductive layer 112 may be formed by chemical vapor deposition (CVD), physical vapor deposition (PVD), or other suitable deposition processes.

Still referring to FIG. 3, the method 200 at operation 204 forms a semiconductor layer 114 over the conductive layer 112. The semiconductor layer 114 may be formed by a suitable deposition process such as CVD. The semiconductor layer 114 may be made of a compound semiconductor material. In the embodiment shown, the compound semiconductor material includes indium gallium zinc oxide (IGZO). In other embodiments, the compound semiconductor material includes oxygen and at least two of the following three materials: indium, gallium, and zinc. In an embodiment, the semiconductor layer 114 is chosen to have high mobility in a polycrystalline or amorphous state. As such, the semiconductor layer 114 can be formed on the conductive layer 112 and does not need to be formed on a semiconducting layer such as silicon. This is because for the material chosen (e.g., IGZO), the semiconductor layer 114 does not require forming single crystalline structures, which would require growing on a semiconducting layer such as silicon. Although not required, selective doping into the semiconductor layer 114 may be performed to reduce oxygen defects and to improve channeling effects. For example, higher dopant concentrations (e.g., gallium) are introduced in the top and bottom portions of the semiconductor layer 114. These top and bottom portions later form source/drain features that interpose a channel of a transistor device.

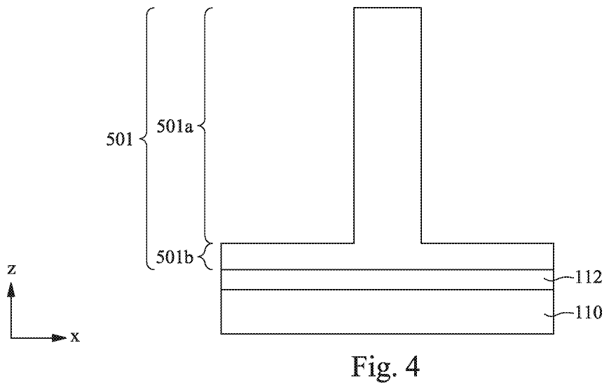

Referring now to FIG. 4, the method 200 at operation 206 patterns the semiconductor layer 114 to form a semiconductor feature 501. The semiconductor feature 501 may be formed by a patterning process that includes lithography and etching. In an embodiment, a lithography process is performed to form a patterned mask layer that covers portions of the semiconductor layer 114, and an etching process is performed using the patterned mask layer as an etch mask. The semiconductor feature 501 includes a first portion 501a over a second portion 501b. The second portion 501b is wider than the first portion 501a. In the embodiment shown, the semiconductor feature 501 has an upside down T shape, where a narrower first portion 501a protrudes above a wider second portion 501b.

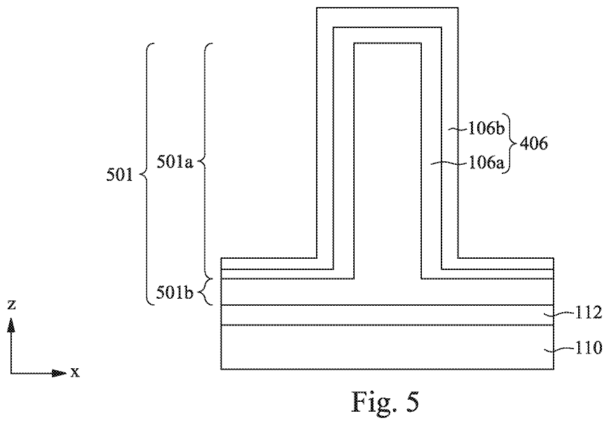

Referring now to FIG. 5, the method 200 at operation 208 forms a gate stack 406 over the semiconductor feature 501 by a suitable deposition process. The gate stack 406 includes a gate dielectric layer 106a and a gate electrode 106b over the gate dielectric layer 106a. The gate dielectric layer 106a may include a high-k dielectric material and the gate electrode 106b may include a suitable conductive material such as titanium nitride. The high-k dielectric material may include hafnium oxide, zirconium oxide, titanium oxide, silicon oxynitride, or other suitable dielectric materials. In some examples (not shown), the gate dielectric layer 106a and the gate electrode 106b each may include a number of sub-layers. Still referring to FIG. 5, the gate stack 406 may be conformally deposited over the semiconductor feature 501. As shown, the gate dielectric layer 106a lands on top and side surfaces of the semiconductor feature 501. Then, the gate electrode 106b lands on top and side surfaces of the gate dielectric layer 106a.

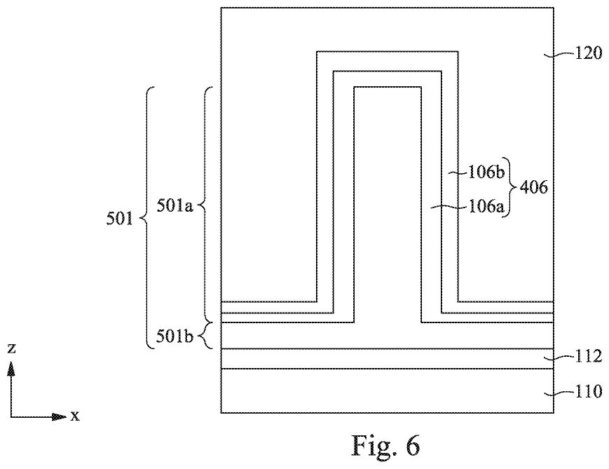

Referring now to FIG. 6, the method 200 at operation 210 forms a second dielectric layer 120 over the gate stack 406 by a suitable deposition process. The second dielectric layer 120 may include similar materials as the dielectric layer 110.

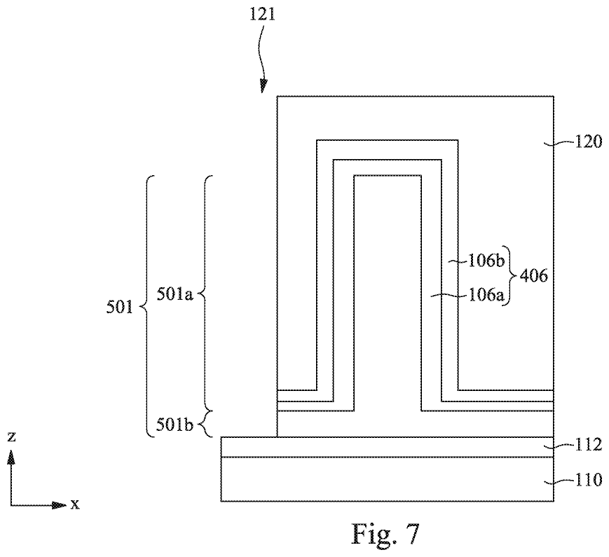

Referring now to FIG. 7, the method 200 at operation 212 etches through the second dielectric layer 120, the gate stack 406, and the second portion 501b of the semiconductor feature 501 to form a trench 121 exposing a landing portion of the conductive layer 112. The trench 121 may be formed by a patterning process that includes lithography and etching. In an embodiment, a lithography process is performed to form a patterned mask layer that covers portions of the second dielectric layer 120, and an etching process is performed using the patterned mask layer as an etch mask.

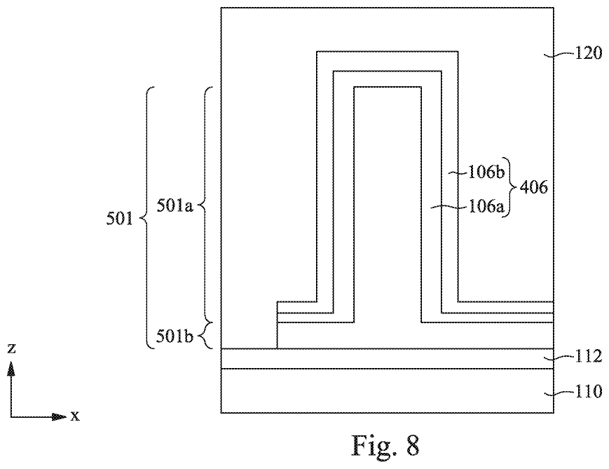

Referring now to FIG. 8, the method 200 at operation 214 reforms the second dielectric layer 120 by filling the trench 121 with a dielectric material. In the present embodiment, the dielectric material includes similar materials as that of the second dielectric layer 120. The dielectric material may be deposited in the trench 121 by any suitable process. In an embodiment, the operation 214 further includes a planarization process such as CMP to level a top surface of the reformed second dielectric layer 120.

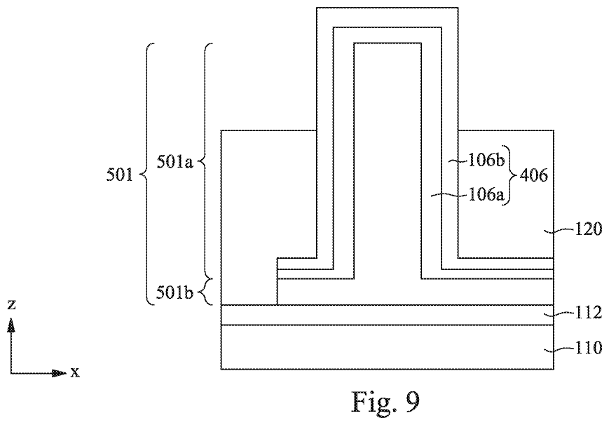

Referring now to FIG. 9, the method 200 at operation 216 performs a pull-back etch to the second dielectric layer 120. The pull-back etch exposes a top portion of the gate stack 406. The second dielectric layer 120 now surrounds and embeds a lower portion of the gate stack 406 (which later becomes the gate structure 506), and the second dielectric layer 120 directly contacts the lower portion of the gate stack 406 and the semiconductor feature 501 (or specifically the second portion 501b of the semiconductor feature 501).

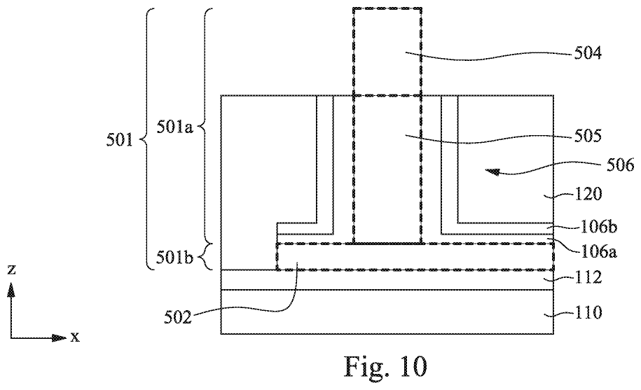

Referring now to FIG. 10, the method 200 at operation 218 etches the top portion of the gate stack 406 to expose a top portion of the semiconductor feature 501. Specifically, with respect to the semiconductor feature 501, a top portion of the first portion 501a is exposed while a bottom portion of the first portion 501a and the second portion 501b remain covered. The second dielectric layer 120 may act as an etch stop and etch mask when etching the top portion of the gate stack 406. The remaining portions of the gate stack 406 forms a gate structure 506. As described previously in FIGS. 1A-1B, the semiconductor feature 501 functions as a transistor 501 and includes portions that correspond to source, drain, and channel. After forming the gate structure 506, the source, drain, and channel portions of the semiconductor feature 501 are defined. For example, the semiconductor feature 501 includes a first S/D feature 502 that corresponds to the drain (or source) of the semiconductor feature 501. The semiconductor feature 501 includes a second S/D feature 504 that corresponds to the source (or drain) of the semiconductor feature 501. And the semiconductor feature 501 includes a channel 505 vertically between the first and second S/D features 502 and 504 that corresponds to the channel of the semiconductor feature 501. As shown in FIG. 10, the gate structure 506 horizontally wraps around the channel 505. The channel 505 is a vertical channel, with source and drain portions above and/or below the channel 505. The first S/D feature 502 corresponds to the second portion 501b of the semiconductor feature 501, the channel 505 corresponds to a bottom portion of the first portion 501a of the semiconductor feature 501, and the second S/D feature 504 corresponds to a top portion of the first portion 501a of the semiconductor feature 501. The first S/D feature 502 directly lands on the conductive layer 112, and the gate structure 506 not only wraps around the channel 505 but also lands on a top surface of the first S/D feature 502. The channel 505 is above the first S/D feature 502 and below the second S/D feature 504. In this embodiment, the channel 505 and the second S/D feature 504 have substantially the same width along an x direction because the channel 505 and the second S/D feature 504 are formed in a same patterning step. The first S/D feature 502 may have a greater width along the x direction than the width of the channel 505 and the second S/D feature 504.

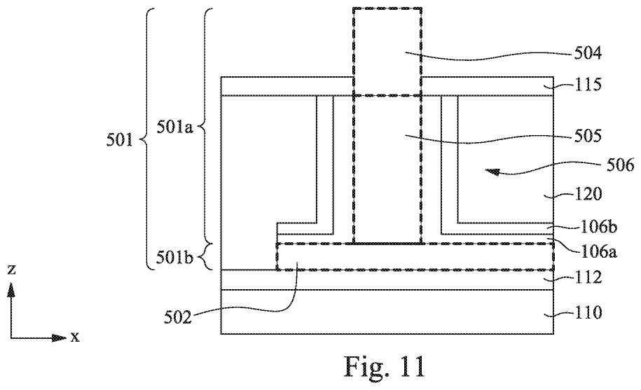

Referring now to FIG. 11, the method 200 at operation 220 forms an insulating layer 115 (or first insulating layer 115) over the gate structure 506 and the second dielectric layer 120. The insulating layer 115 may be formed by a directional deposition process such that the insulating layer 115 is formed only (or substantially) on top surfaces of the gate structure 506, the second dielectric layer 120, and the second S/D feature 504. Then, an etching process may be performed by etching away portions of the insulating layer 115 on the top surface of the second S/D feature 504 and part of the top portion of the second S/D feature 504. As a result, the insulating layer 115 is formed as shown, on top surfaces of the gate structure 506, the second dielectric layer 120, and partially on side surfaces of the second S/D feature 504. After the formation of the insulating layer 115, a top portion of the second S/D feature 504 remain exposed. The insulating layer 115 may be an etch stop layer that includes silicon nitride. In an embodiment, the insulating layer 115 includes a different dielectric material than that of the dielectric layers 110 and 120 for etchant selectivity.

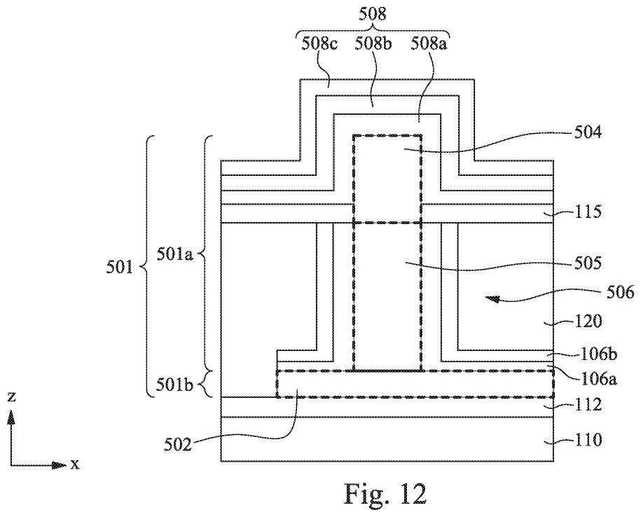

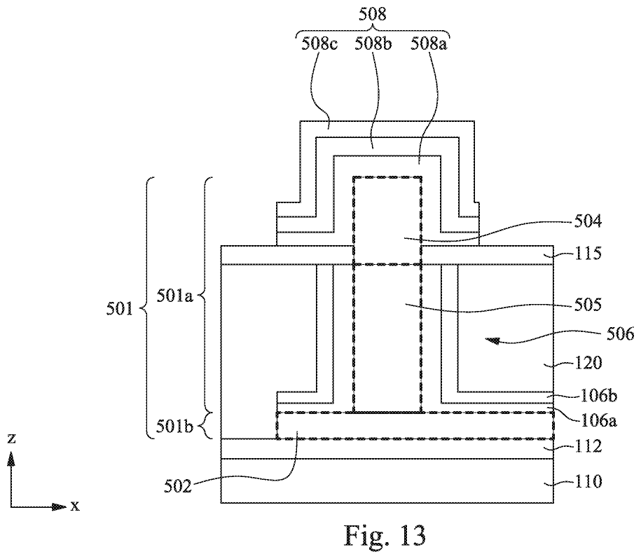

Referring now to FIGS. 12-13, the method 200 at operation 222 forms a capacitor structure 508 over the insulating layer 115 and over side and top surfaces of the exposed top portion of the second S/D feature 504. The capacitor structure 508 may be a metal-insulator-metal (MIM) capacitor structure having electrodes 508a and 508c separated by an insulator 508b. The electrodes 508a and 508c may include any suitable conductive material such as titanium nitride. The insulator 508b may include a high-k dielectric material like the ones previously described. The electrode 508a directly contacts and lands on the second S/D feature 504 of the semiconductor feature 501 and on the insulating layer 115. The capacitor structure 508 may be formed by first conformally depositing layers for the electrode 508a, the insulator 508b, and the electrode 508c (see FIG. 12), then a patterning process is performed to etch away portions of the deposited layers landing on the insulating layer 115 (see FIG. 13). The capacitor structure 508 may directly land on top surfaces of the insulating layer 115, and so the insulating layer is vertically between and may directly contact both the capacitor structure 508 and the gate structure 506. As shown in FIG. 13, portions of the insulating layer 115 are exposed. In the present embodiment, the capacitor structure 508 directly contacts and horizontally wraps around the second S/D feature 504.

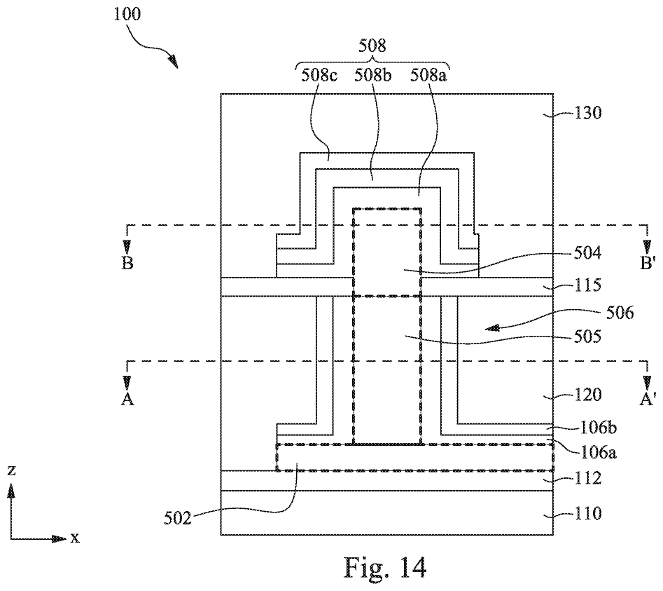

Referring now to FIG. 14, the method 200 at operation 224 forms a third dielectric layer 130 over the capacitor structure 508 by a suitable deposition process. The third dielectric layer 130 may include similar materials as the dielectric layers 110 and 120. The third dielectric layer 130 surrounds and embeds the capacitor structure 508. The third dielectric layer 130 directly contacts the capacitor structure 508 (including the electrode 508a, the insulator 508b, and the electrode 508c) and directly contacts top surfaces of the insulating layer 115. As shown, the insulating layer 115 separates the second dielectric layer 120 (a first level ILD layer) from the third dielectric layer 130 (a second level ILD layer) and separates the gate structure 506 from the capacitor structure 508. The method 200 now forms a memory device 100 having a transistor 501 and a capacitor 508 above the transistor 501. To tune for lower capacitance, and as shown in FIG. 14, the height of the second S/D feature 504 along the z direction may be smaller than the height of the channel 505 along the z direction. In a different embodiment, to tune for higher capacitance, the height of the second S/D feature 504 along the z direction may be greater than the height of the channel 505 along the z direction. In other words, the height dimensions and ratio between the second S/D feature 504 and the channel 505 may be adjusted to meet low leakage current and high capacitance density goals.

FIG. 14 includes a line A-A′ across the channel 505 and a line B-B′ across the second S/D feature 504. FIGS. 15A-1, 15A-2, and 15A-3 illustrate top views of the memory device 100 in FIG. 14, cut along the lines A-A′, according to different embodiments of the present disclosure. FIGS. 15B-1, 15B-2, and 15B-3 illustrate top views of the memory device 100 in FIG. 14, cut along the lines B-B′, according to different embodiments of the present disclosure.

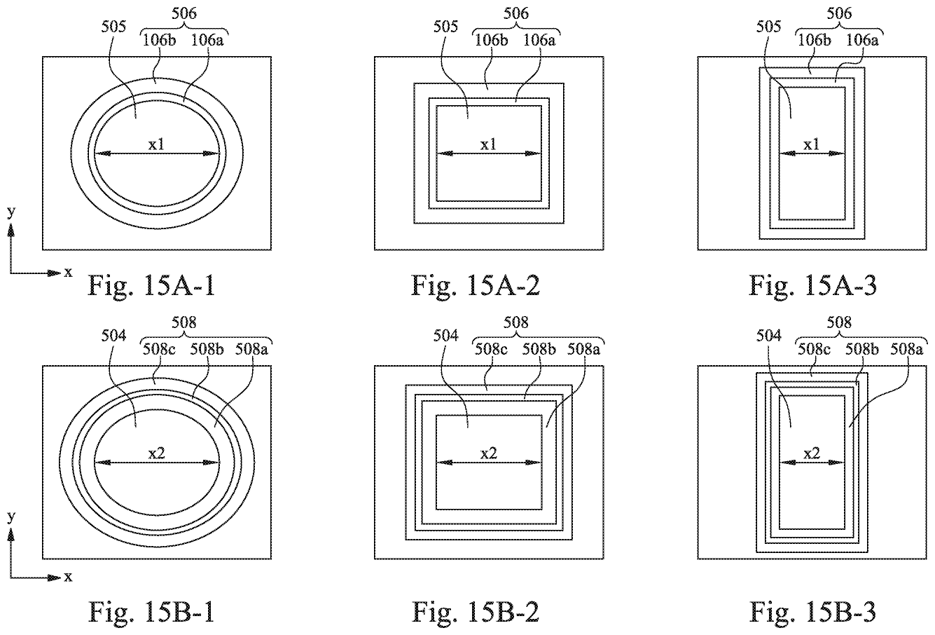

Referring now to FIGS. 15A-1, 15A-2, and 15A-3, the channel 505 may be fully wrapped around by the gate structure 506 in the x-y plane. The gate structure 506 includes the gate dielectric layer 106a that directly contacts and fully wraps around the channel 505. The gate structure 506 further includes the gate electrode 106b that directly contacts and fully wraps around the gate dielectric layer 106a. In an embodiment, the channel 505 has a circular shape in the x-y plane (see FIG. 15A-1). In another embodiment, the channel 505 has a square shape in the x-y plane (see FIG. 15A-2). In another embodiment, the channel 505 has a rectangular shape in the x-y plane (see FIG. 15A-3).

Referring now to FIGS. 15B-1, 15B-2, and 15B-3, the second S/D feature 504 may be fully wrapped around by the capacitor structure 508 in the x-y plane. The capacitor structure 508 includes the electrode 508a that directly contacts and fully wraps around the second S/D feature 504. The capacitor structure 508 includes the insulator 508b that directly contacts and fully wraps around the electrode 508a. The capacitor structure 508 further includes the electrode 508c that directly contacts and fully wraps around the insulator 508b. Although not shown, the capacitor structure 508 may include additional interleaved metal and insulator layers between the electrodes 508a and 508c. In an embodiment, the second S/D feature 504 has a circular shape in the x-y plane (see FIG. 15B-1). In another embodiment, the second S/D feature 504 has a square shape in the x-y plane (see FIG. 15B-2). In another embodiment, the second S/D feature 504 has a rectangular shape in the x-y plane (see FIG. 15B-3).

Each of the FIGS. 15A-1, 15A-2, and 15A-3 shows a width x1 of the respective channels 505. Each of the FIGS. 15B-1, 15B-2, and 15B-3 shows a width x2 of the respective second S/D features 504. In the present embodiment, for each corresponding pair of channel 505 and second S/D feature 504, the width x1 is the same or substantially the same as the width x2 (e.g., x1 in FIG. 15A-1 is the same or substantially the same as x2 in FIG. 15B-1). This is because the channel 505 and the second S/D feature 504 may be formed in a same patterning process as described with respect to FIG. 4 (i.e., they are both part of the first portion 501a).

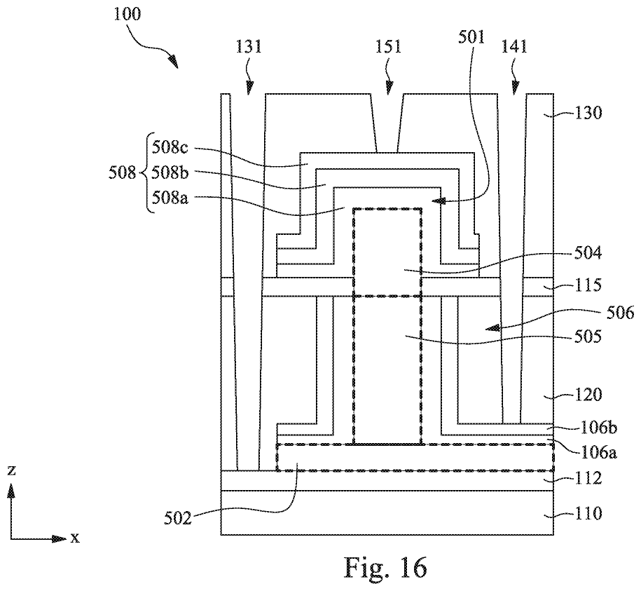

Referring now to FIG. 16, the method 200 at operation 226 forms a first via trench 131 through the third dielectric layer 130, the insulating layer 115, and the second dielectric layer 120. The first via trench 131 exposes a portion of the conductive layer 112. The exposed portion of the conductive layer 112 may be part of the landing portion of the conductive layer 112 described in FIG. 7. The third dielectric layer 130, the insulating layer 115, and the second dielectric layer 120 may be etched in a same or separate etching process when forming the first via trench 131. In one embodiment, the first via trench 131 is separately etched using different etching parameters when etching the dielectric layers 130 and 120 versus the insulating layer 115.

Still referring to FIG. 16, the method 200 at operation 228 forms a second via trench 141 through the third dielectric layer 130, the insulating layer 115, and the second dielectric layer 120. The second via trench 141 exposes the gate structure 506. The exposed portion of the gate structure 506 is a horizontal portion of the gate structure 506 that is directly on and above the first S/D feature 502. Specifically, the second via trench 141 exposes a horizontal surface of the gate electrode 106b. The trench depth of the second via trench 141 is not as deep as the first via trench 131. The third dielectric layer 130, the insulating layer 115, and the second dielectric layer 120 may be etched in a same or separate etching process when forming the second via trench 141. In one embodiment, the second via trench 141 is separately etched using different etching parameters when etching the dielectric layers 130 and 120 versus the insulating layer 115.

Still referring to FIG. 16, the method 200 at operation 230 forms a third via trench 151 through the third dielectric layer 130. The third via trench 151 exposes the capacitor structure 508. The exposed portion of the capacitor structure 508 may be a top horizontal surface of the capacitor structure 508. Specifically, the third via trench 151 exposes the electrode 508c of the capacitor structure 508. As shown, the trench depth of the third via trench 151 may be much shallower than the first via trench 131 and the second via trench 141. This is because the third via trench 151 does not penetrate through the insulating layer 115. To prevent over-etching and damaging the electrode 508c, the third via trench 151 may be separately formed from the first and second via trenches 131 and 141. For example, the first and second via trenches 131 and 141 may be formed together in a first patterning process that includes lithography and etching, then the third via trench 151 is formed in a second patterning process that includes lithography and etching. In another embodiment, the first and second via trenches 131 and 141 may be partially formed in a first patterning process by etching these trenches to a first depth. Then in a second patterning process, the first, second, and third via trenches 131, 141, and 151 are formed together by further etching the first and second via trenches 131 and 141 to a second depth exposing the conductive layer 112 and the gate structure 506 and etching the third via trench 151 exposing the capacitor structure 508. In further embodiments, the first, second, and third via trenches 131, 141, and 151 may all be separately formed in separate patterning processes.

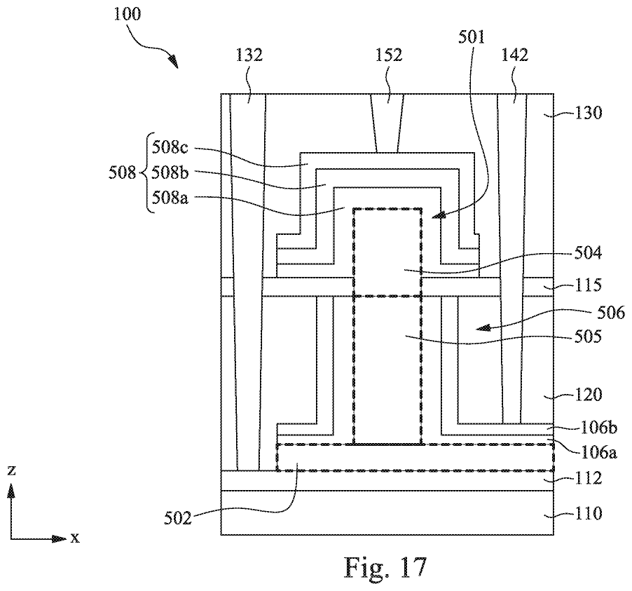

Referring now to FIG. 17, the method 200 at operation 232 forms a first via 132, a second via 142, and a third via 152 in the first, second, and third via trenches 131, 141, and 151, respectively. These vias may be formed by any suitable deposition techniques such as PVD or CVD to deposit a metal material in the first, second, and third via trenches 131, 141, and 151. Then, a CMP process may be performed to remove any overfill of the metal material and level the memory device 100, thereby forming the first, second, and third vias 132, 142, and 152. The metal material of the first, second, and third vias 132, 142, and 152 may include titanium (Ti), ruthenium (Ru), copper (Cu), nickel (Ni), cobalt (Co), tungsten (W), tantalum (Ta), molybdenum (Mo), or a combination thereof.

Still referring to FIG. 17, the first via 132 directly lands on the conductive layer 112, which is electrically connected to the first S/D feature 502 of the semiconductor feature 501. The first via 132 corresponds to a bit line via that electrically routes to a bit line of the memory device 100. The second via 142 directly lands on the gate structure 506, which wraps around the channel 505 of the semiconductor feature 501. The second via 142 corresponds to a word line via that electrically routes to a word line of the memory device 100. The third via 152 directly lands on the capacitor structure 508, which is electrically connected to the second S/D feature 504 of the semiconductor feature 501. Specifically, the electrode 508c directly contacts the third via 152, and the electrode 508a directly contacts the second S/D feature 504. The third via 152 corresponds to a ground line via that electrically routes to a ground line of the memory device 100.

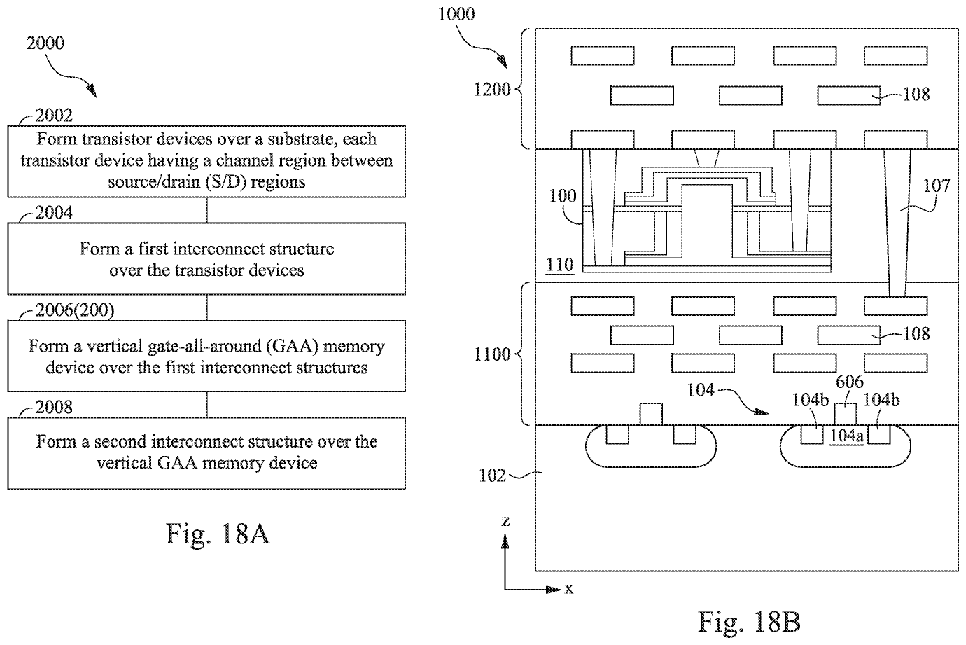

FIG. 18A illustrates a flow chart of a method 2000 to form an integrated circuit 1000 that includes the memory device 100 in FIG. 1B (or FIG. 17), according to an embodiment of the present disclosure. FIG. 18B illustrates the integrated circuit 1000 formed by the method 2000 of FIG. 18A. Referring to FIGS. 18A and 18B, the method 2000 at operation 2002 forms transistor devices 104 over a substrate 102. The transistor devices 104 may be different from the memory device 100 described previously. In an embodiment, the transistor devices 104 are logic devices. Each of the transistor devices 104 includes a channel region 104a between source/drain (S/D) regions 104b. The channel region 104a and S/D regions 104b may be part of an active region over the substrate 102. Each transistor device 104 includes a gate 606 over the channel region 104a. The transistor devices 104 may be planar devices (as shown) or they could be fin field-effect-transistors (FETs) or gate-all-around (GAA) FETs.

Referring now to operation 2004, the method 2000 forms a first interconnect structure 1100 over the transistor devices. The first interconnect structure 1100 includes metal contacts such as S/D contacts and gate contacts (not explicitly shown) that land on the S/D region 104b and the gate 606, vias such as S/D vias and gate vias (not explicitly shown) that land on the metal contacts, and metal lines 108 that land on and electrically connect to the various metal contacts and vias. The various metal contacts, vias, and metal lines of the interconnect structure 1100 may be surrounded by or embedded in an interlayer dielectric layer (ILD). Referring now to operation 2006, the method 2000 forms a vertical GAA memory device 100 over the first interconnect structures 1100. The vertical GAA memory device 100 may be formed by the method 200 as described previously. In the embodiment shown, the memory device 100 is formed over a dielectric layer 110 above the first interconnect structure 1100. The dielectric layer 110 may also surround the memory device 100 and embed other features such as a through-via 107. Referring now to operation 2008, the method 2000 forms a second interconnect structure 1200 over the vertical GAA memory device 100. The second interconnect structure 1200 includes various metal lines 108 that electrically connect to the memory device 100. For example, some of these metal lines 108 may land on the first, second, and third vias 132, 142, and 152. These metal lines 108 are then connected to higher level metal lines 108 for further routing. Some of the metal lines 108 in the second interconnect structure 1200 may land on through-vias 107, which bypasses the memory device 100 to land on a metal line 108 in the first interconnect structure 1100.

As shown and described with respect to FIGS. 18A and 18B, the memory device 100 of FIG. 1B (or FIG. 17) may be incorporated and sandwiched between metal lines 108. These metal lines 108, whether in the first or second interconnect structure 1100 or 1200, are frontside metal lines formed over transistor devices 104. In some embodiments, because of the increased device density benefits of the memory device 100, a vertical spacing between the metal lines 108 that sandwich the memory device 100 is about the same as a vertical spacing between metal lines 108 that do not sandwich any memory device 100. In other embodiments, the spacing between the metal lines 108 that sandwich the memory device 100 is larger than the spacing between metal lines 108 that do not sandwich any memory devices 100. Note that multiple memory devices 100 may be configured between various metal lines 108. In an embodiment, the formed integrated circuit 1000 may include multiple vertical GAA transistors for memory devices 100 and multiple horizontal GAA transistors for logic devices (i.e., transistor devices 104). That is, the memory devices 100 have vertical channels horizontally wrapped by gate electrodes, and the logic devices (i.e., transistor devices 104) have horizontal channels vertically wrapped by gate electrodes.

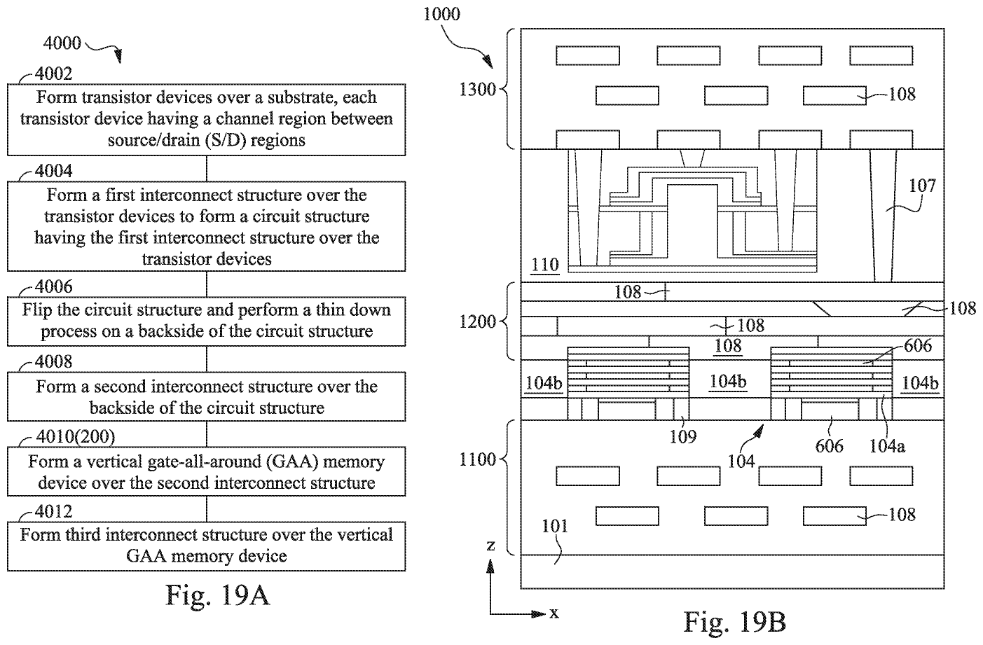

FIG. 19A illustrates a flow chart of a method 4000 to form an integrated circuit 1000 that includes the memory device 100 in FIG. 1B (or FIG. 17), according to another embodiment of the present disclosure. FIG. 19B illustrates the integrated circuit 1000 formed by the method 4000 of FIG. 19A. Referring to FIGS. 19A and 19B, the method 4000 at operation 4002 forms transistor devices 104 over a substrate (the substrate is not shown). The transistor devices 104 may be different from the memory device 100 described previously. In an embodiment, the transistor devices 104 are logic devices. Each of the transistor devices 104 includes a channel region 104a between source/drain (S/D) regions 104b. In the embodiment shown, the channel region 104a may include a stack of multiple channel layers that connect between S/D regions 104b. Each transistor device 104 includes a gate 606 over the channel region 104a. However, as shown in FIG. 19B, the gate 606 is disposed under the channel region 104a after flipping the circuit structure in operation 4006. The gate 606 may include gate dielectric and gate electrodes and the gate 606 may have portions that vertically wrap around multiple channel layers. Each transistor devices 104 may include spacers 109 such as gate spacers, inner spacers, or other insulating spacers that insulate between channel layers, gate structures, and other relevant surrounding features. In some embodiments, the spacers 109 includes a dielectric material that includes silicon, oxygen, carbon, nitrogen, other suitable material, or combinations thereof (for example, silicon oxide, silicon nitride, silicon oxynitride, silicon carbide, or silicon oxycarbonitride). In some embodiments, the spacer layer includes a low-k dielectric material. The transistor devices 104 may be GAA FETs as shown, or they could be planar devices or fin FET devices.

Referring now to operation 4004, the method 4000 forms a first interconnect structure 1100 over the transistor devices 104, thereby forming a circuit structure having the first interconnect structure 1100 and the transistor devices 104. Note that FIG. 19B shows the first interconnect structure 1100 under the transistor devices 104. This is because the circuit structure is flipped upside down in a later fabrication step. The first interconnect structure 1100 includes metal contacts such as S/D contacts and gate contacts (not explicitly shown) that land on the S/D region 104b and the gate 606, vias such as S/D vias and gate vias (not explicitly shown) that land on the metal contacts, and metal lines 108 that land on and electrically connect to the various metal contacts and vias. The various metal contacts, vias, and metal lines of the interconnect structure 1100 may be surrounded by or embedded in an interlayer dielectric layer (ILD). Referring now to operation 4006, the method 4000 flips the circuit structure having the first interconnect structure 1100 and the transistor devices 104 and performs a thin down process on a backside of the circuit structure. The operation 4006 may include forming a bonding substrate 101 over the interconnect structure 1100 for structural integrity, then flipping the whole workpiece and performing a thin down process to remove portions of the circuit structure where the transistor devices 104 are first formed over. Referring now to operation 4008, the method 4000 forms a second interconnect structure 1200 over a backside of the circuit structure (since it is now flipped). The second interconnect structure 1200 includes various metal lines 108 that electrically connect to the transistor device 104. For example, some of these metal lines 108 may include backside vias that land from the backside onto the S/D regions 104b of the transistor devices 104, and backside conductive lines that land on the backside vias. These backside conductive lines may also be referred to as backside power rails for routing power from a backside of the transistor devices 104. These metal lines 108 are then connected to metal lines 108 in the third interconnect structure for further routing. Referring now to operation 4010, the method 4000 forms a vertical GAA memory device 100 over the second interconnect structure 1200. The vertical GAA memory device 100 may be formed by the method 200 as described previously. In the embodiment shown, the memory device 100 is formed over a dielectric layer 110 above the second interconnect structure 1200. The dielectric layer 110 may also surround the memory device 100 and embed other features such as a through-via 107. Referring now to operation 4012, the method 4000 forms a third interconnect structure 1300 over the vertical GAA memory device 100. As such, the vertical GAA memory device 100 is formed between backside power rails in the second interconnect structure 1200 and the metal routings in the third interconnect structure 1300. The third interconnect structure 1300 includes various metal lines 108 that electrically connect to the memory device 100. For example, some of these metal lines 108 may land on the first, second, and third vias 132, 142, and 152. These metal lines 108 are then connected to higher level metal lines 108 for further routing. Some of the metal lines 108 in the third interconnect structure 1300 may land on through-vias 107, which bypasses the memory device 100 to land on a metal line 108 in the second interconnect structure 1200.

As shown and described with respect to FIGS. 19A and 19B, the memory device 100 of FIG. 1B (or FIG. 17) may be incorporated and sandwiched between metal lines 108. These metal lines 108 are backside metal lines formed on a backside of the transistor devices 104. In some embodiments, because of the increased device density benefits of the memory device 100, a vertical spacing between the metal lines 108 that sandwich the memory device 100 is about the same as a vertical spacing between metal lines 108 that do not sandwich any memory device 100. In other embodiments, the spacing between the metal lines 108 that sandwich the memory device 100 is larger than the spacing between metal lines 108 that do not sandwich any memory devices 100. Note that multiple memory devices 100 may be configured between various metal lines 108. In an embodiment, the formed integrated circuit 1000 may include multiple vertical GAA transistors for memory devices 100 and multiple horizontal GAA transistors for logic devices (i.e., transistor devices 104). That is, the memory devices 100 have vertical channels horizontally wrapped by gate electrodes, and the logic devices (i.e., transistor devices 104) have horizontal channels vertically wrapped by gate electrodes.

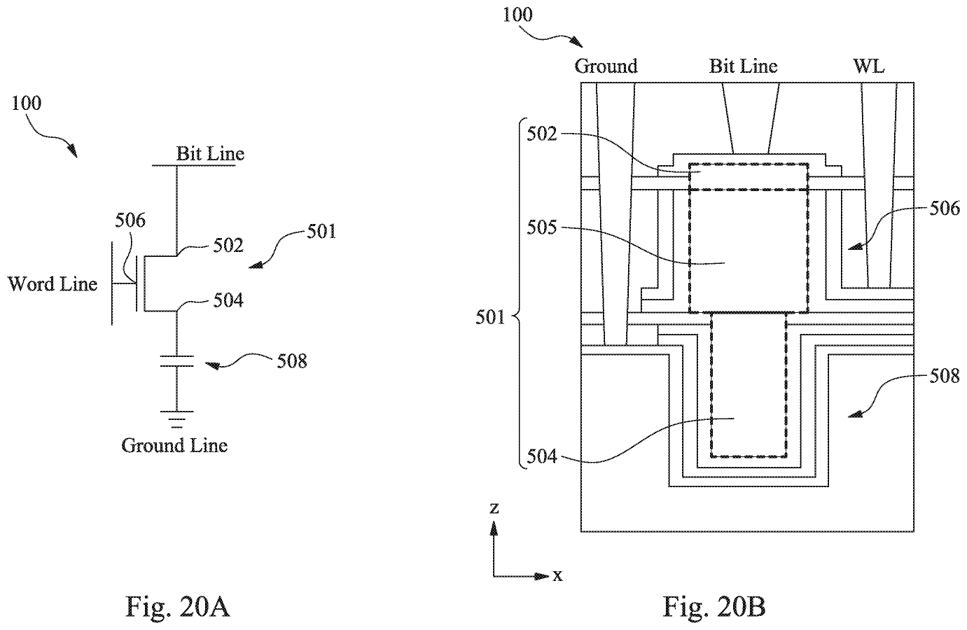

FIG. 20A illustrates a circuit diagram of a memory device 100 having a transistor 501 and a capacitor 508. The circuit diagram in FIG. 20A resembles the circuit diagram in FIG. 1A. As shown, the transistor 501 has a first terminal corresponding to a first source/drain (S/D) feature 502, a second terminal corresponding to a second S/D feature 504, and a third terminal corresponding to a gate 506. The gate 506 controls a channel between the first and second S/D features 502 and 504. The gate 506 is electrically connected to a word line of the memory device 100. The first S/D feature 502 (i.e., first terminal of transistor 501) is electrically connected to a bit line of the memory device 100, and the second S/D feature 504 (i.e., second terminal of transistor 501) is electrically connected to a capacitor 508, which is then electrically connected to a ground line. In an embodiment, the first S/D feature 502 corresponds to drain and the second S/D feature 504 corresponds to source. In this case, the drain of the transistor 501 is connected to a bit line, the source of the transistor 501 is connected to a first terminal (or electrode) of the capacitor 508, and a second terminal (or electrode) of the capacitor 508 is connected to a ground line. In another embodiment, the first S/D feature 502 corresponds to source and the second S/D feature 504 corresponds to drain. In this case, the source of the transistor 501 is connected to a bit line, the drain of the transistor 501 is connected to a first terminal (or electrode) of the capacitor 508, and a second terminal (or electrode) of the capacitor 508 is connected to a ground line. The bit line, word line, and ground line correspond to different connection nodes, and these nodes may be connected to other transistors 501 and other capacitors 508 in other memory devices 100. In an embodiment, the bit line, word line, and ground line are metal lines in a metal interconnect structure, and they connect to multiple memory devices 100 in a memory array.

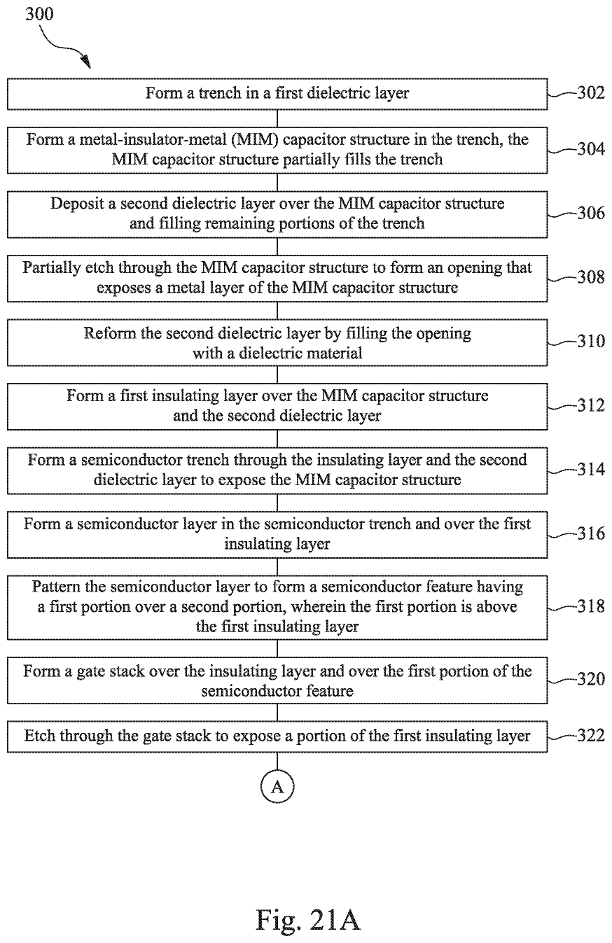

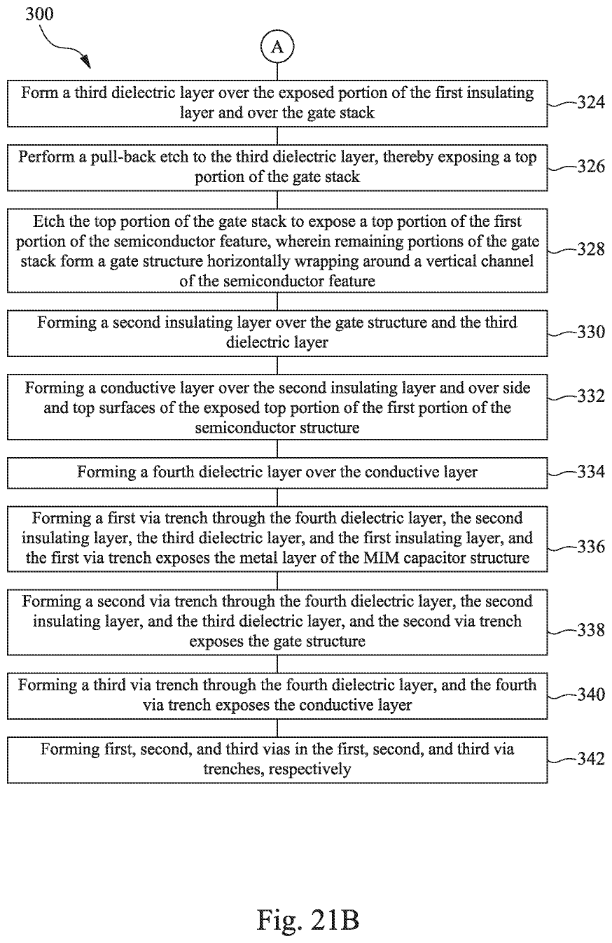

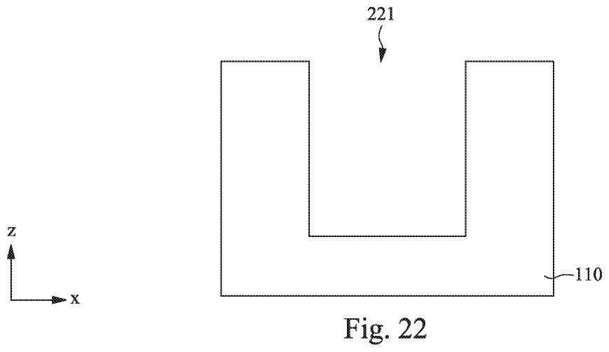

FIG. 20B illustrates a cross sectional-view of the memory device 100 in FIG. 20A, according to another embodiment of the present disclosure. Features described in FIG. 20A are similarly labeled in FIG. 20B. Note that there are additional features shown in FIG. 20B that will be described in more detail with respect to the method 300 in FIGS. 21A and 21B and the formation of the memory device 100 in FIGS. 22-43 and 45-46. Note that the memory device 100 shown in FIG. 20B has a different structure than the memory device 100 shown in FIG. 1B. In FIG. 1B, the capacitor structure 508 is disposed vertically above the channel 505 of the transistor 501, and in FIG. 20B, the capacitor structure 508 is disposed vertically below the channel 505 of the transistor 501.

FIG. 20B shows a transistor 501 (also referred to as a semiconductor feature 501) having different portions that corresponds to source, drain, and channel. The semiconductor feature 501 may be made of a compound semiconductor material. In the embodiment shown, the compound semiconductor material includes indium gallium zinc oxide (IGZO). In other embodiments, the compound semiconductor material includes oxygen and at least two of the following three materials: indium, gallium, and zinc. In further embodiments, the semiconductor feature 501 may include hafnium oxide (HfO₂). In an embodiment, the semiconductor feature 501 is chosen to have high mobility in a polycrystalline or amorphous state. In other words, the semiconductor feature 501 does not have a crystalline structure but instead has an amorphous or polycrystalline structure. As such, the semiconductor feature 501 does not need to be formed on a semiconducting layer such as silicon but can be formed on a conductive layer such as titanium nitride.

Still referring to FIG. 20B, a gate 506 horizontally wraps around a channel 505 of the semiconductor feature 501. In this cross-sectional view, the gate 506 is disposed on sidewalls of the channel 505. S/D features 502 and 504 of the semiconductor feature 501 are vertically above and below the channel 505. Described in another way, the semiconductor feature 501 includes a first portion (i.e., the first S/D feature 502) over a second portion (i.e., channel 505), and the second portion (i.e., channel 505) is over a third portion (i.e., second S/D feature 504). The second portion (i.e., channel 505) is vertically between and vertically extends from the first portion (i.e., first S/D feature 502) to the third portion (i.e., second S/D feature 504). As shown, a capacitor 508 is in direct contact with and horizontally wrapping around the third portion (i.e., second S/D feature 504) of the semiconductor feature 501. In this case, the capacitor 508 is vertically stacked below the semiconductor feature 501. As will be described in more detail below, the first S/D feature 502 may be electrically connected to a bit line through a bit line via, the capacitor 508 may be electrically connected to a ground line through a ground line via, and the gate 506 may be electrically connected to a word line through a word line via.

FIGS. 21A-21B illustrate a flow chart of a method 300 to form a memory device 100 having a transistor 501 and a capacitor 508, according to another embodiment of the present disclosure. FIGS. 22-41 and 43-44 illustrate the formation of a memory device 100 at intermediate stages of fabrication and processed in accordance with the method 300 of FIGS. 21A-21B, according to an embodiment of the present disclosure. The method 300 is described below with reference to FIGS. 22-41 and 43-44.

Referring now to FIG. 22, the method 300 at operation 302 forms a trench 221 in a dielectric layer 110 (or first dielectric layer 110) by a suitable patterning process. The dielectric layer 110 may be a base interlayer dielectric (ILD) layer from which the memory device 100 will be formed on. The dielectric layer 110 includes a dielectric material including, for example, silicon oxide, silicon nitride, silicon oxynitride, TEOS formed oxide, PSG, BPSG, low-k dielectric material, other suitable dielectric material, or combinations thereof. In an embodiment, the dielectric layer 110 includes silicon oxide or a low-k dielectric material.

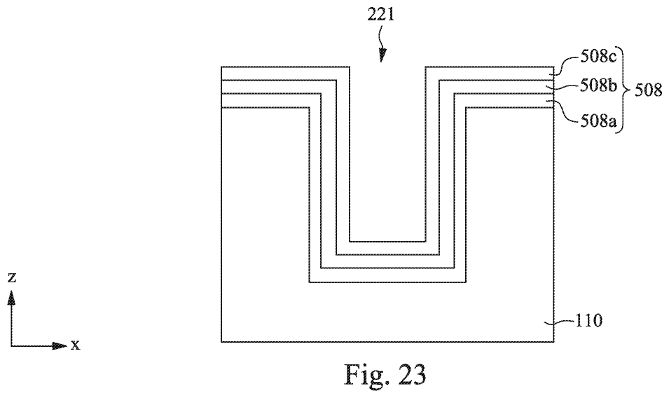

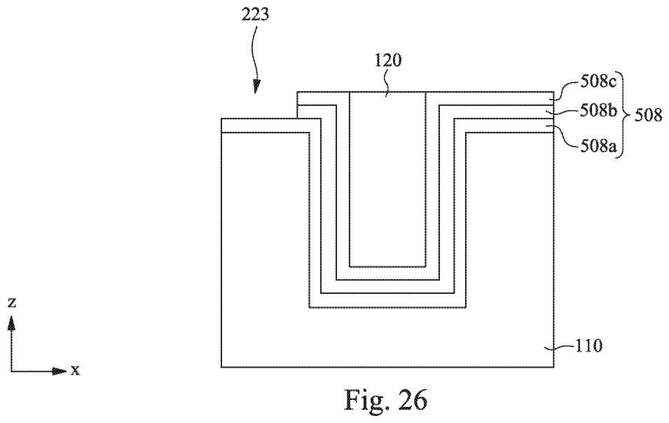

Referring now to FIG. 23, the method 300 at operation 304 forms a capacitor structure 508 in the trench 221, and the capacitor structure 508 partially fills the trench 221. The capacitor structure 508 may be a metal-insulator-metal (MIM) capacitor structure having electrodes 508a and 508c separated by an insulator 508b. The electrodes 508a and 508c may include any suitable conductive material such as titanium nitride. The insulator 508b may include a high-k dielectric material like the ones previously described. The electrode 508a directly contacts and lands on the dielectric layer 110 along surfaces of the trench 221 and on a top surface of the dielectric layer 110. The capacitor structure 508 may be formed by conformally depositing layers for the electrode 508a, the insulator 508b, and the electrode 508c. At a later step, a patterning process may be performed to etch away portions of the deposited layers for the electrode 508c and insulator 508b (see FIG. 26).

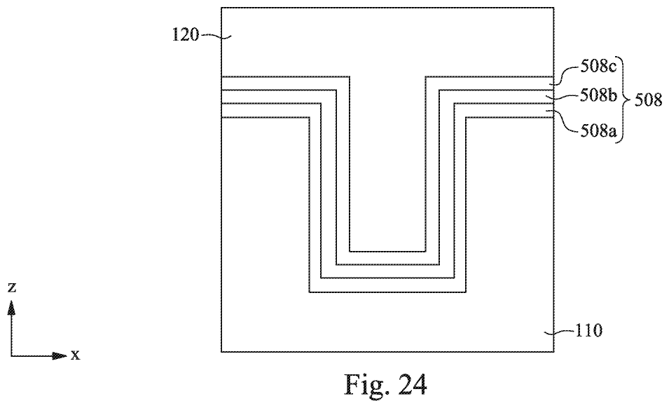

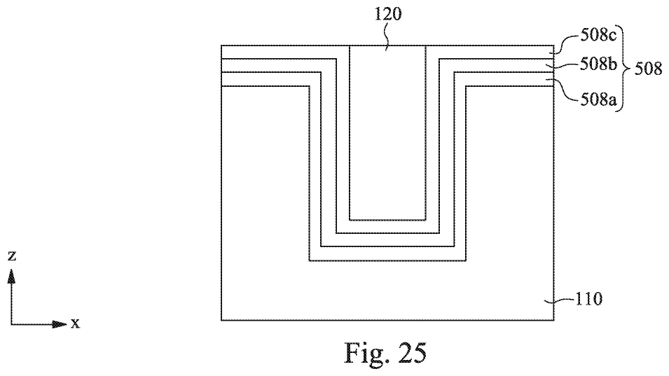

Referring now to FIGS. 24-25, the method 300 at operation 306 forms a second dielectric layer 120 over the capacitor structure 508 that fills remaining portions of the trench 221. The operation 306 may include depositing a dielectric material in the trench 221 by a suitable deposition process. Note that the dielectric material overfills the trench (FIG. 24). Then, a planarization process such as CMP is performed to planarize top surfaces of the capacitor structure 508 and the deposited dielectric material (FIG. 25). The deposited dielectric material forms the second dielectric layer 120, and the second dielectric layer 120 may include similar materials as the dielectric layer 110.

Referring now to FIG. 26, the method 300 at operation 308 partially etches through the capacitor structure 508 to form an opening 223 that exposes a metal layer (i.e., the electrode 508a) of the capacitor structure 508. For example, a suitable patterning process is performed to etch away portions of the deposited layers for the electrode 508c and insulator 508b to expose a portion of the electrode 508a.

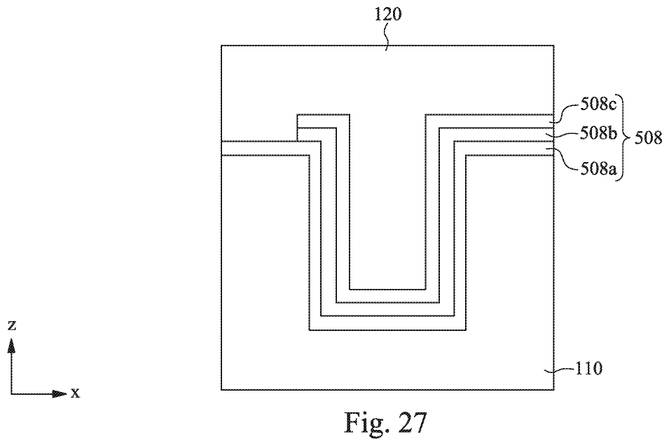

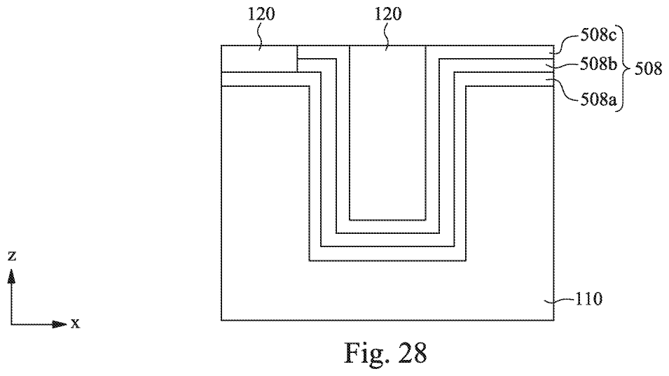

Referring now to FIGS. 27-28, the method 300 at operation 310 reforms the second dielectric layer 120. The operation 306 may include depositing a dielectric material of the second dielectric layer 120 in the opening 223 and over top surfaces of the capacitor structure 508 and the second dielectric layer 120 (FIG. 27). Then, a planarization process such as CMP is performed to planarize top surfaces of the capacitor structure 508 and the deposited dielectric material (FIG. 28). As shown, the second dielectric layer 120 includes portions inside the opening 223 and inside the trench 221. The second dielectric layer 120 is substantially coplanar to the topmost surface of the capacitor structure 508 (i.e., electrode 508c).

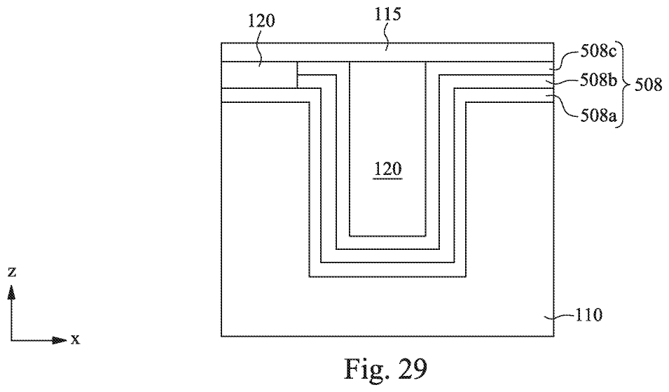

Referring now to FIG. 29, the method 300 at operation 312 forms an insulating layer 115 (or first insulating layer 115) over the capacitor structure 508 and the second dielectric layer 120. The insulating layer 115 may be formed by any suitable deposition process. The insulating layer 115 may be an etch stop layer that includes silicon nitride. In an embodiment, the insulating layer 115 includes a different dielectric material than that of the dielectric layers 110 and 120 for etchant selectivity.

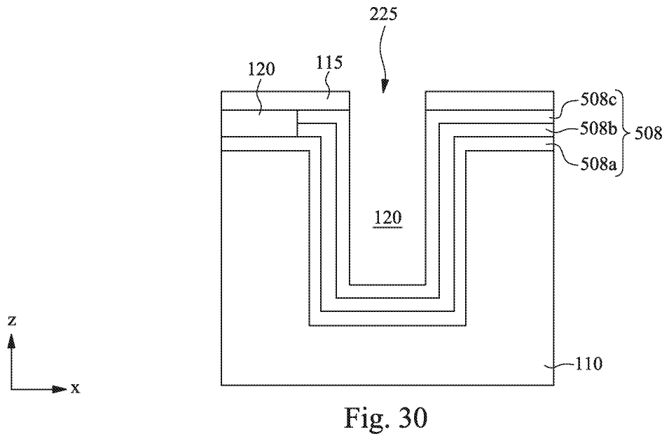

Referring now to FIG. 30, the method 300 at operation 314 forms a semiconductor trench 225 through the insulating layer 115 and the second dielectric layer 120 to expose the capacitor structure 508. The semiconductor trench 225 may be formed by a suitable patterning process that includes lithography and etching. For example, a lithography process is performed to form a patterned mask layer that covers portions of the insulating layer 115, and an etching process is performed using the patterned mask layer as an etch mask. The etching process may include a first etching process that etches the insulating layer 115 and a second etching process that etches the second dielectric layer 120. In another embodiment, the etching process etches through both the insulating layer 115 and the second dielectric layer 120 in a same etching process. The etching process etches away the second dielectric layer 120 that was in the trench 221, thereby exposing the electrode 508c of the capacitor structure 508.

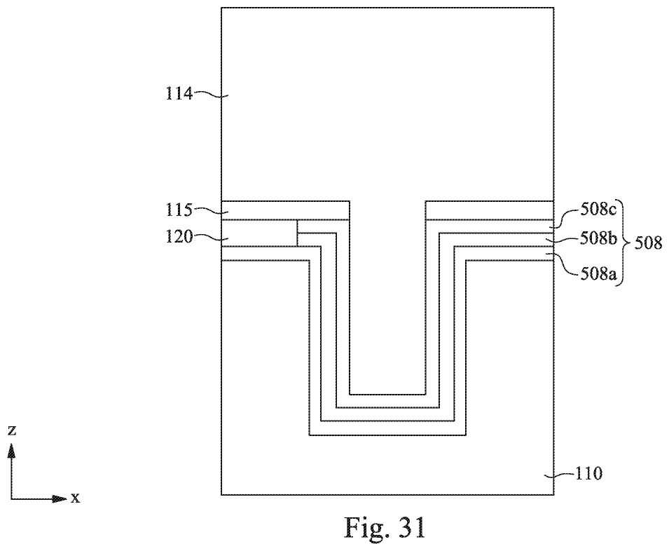

Referring now to FIG. 31, the method 300 at operation 316 forms a semiconductor layer 114 in the semiconductor trench 225 and over the first insulating layer 115. Portions of the semiconductor layer 114 in the semiconductor trench 225 directly contact and are horizontally wrapped by the capacitor structure 508. The semiconductor layer 114 may be formed by a suitable deposition process such as CVD. The semiconductor layer 114 may be made of a compound semiconductor material. In the embodiment shown, the compound semiconductor material includes indium gallium zinc oxide (IGZO). In other embodiments, the compound semiconductor material includes oxygen and at least two of the following three materials: indium, gallium, and zinc. In further embodiments, the semiconductor layer 114 may include hafnium oxide (HfO₂). In an embodiment, the semiconductor layer 114 is chosen to have high mobility in a polycrystalline or amorphous state. As such, the semiconductor layer 114 can be formed on the capacitor structure 508 (e.g., electrode 508c) and does not need to be formed on a semiconducting layer such as silicon. This is because for the material chosen (e.g., IGZO), the semiconductor layer 114 does not require forming single crystalline structures, which would require growing on a semiconducting layer such as silicon. Although not required, the semiconductor layer 114 may include a gradation of dopants to reduce oxygen defects and to improve channeling effects. For example, higher dopant concentrations (e.g., gallium) are introduced in the top and bottom portions of the semiconductor layer 114. The dopants may be introduced by a suitable deposition process when forming the semiconductor layer 114. These top and bottom portions later form source/drain features that interpose a vertical channel of a transistor device.

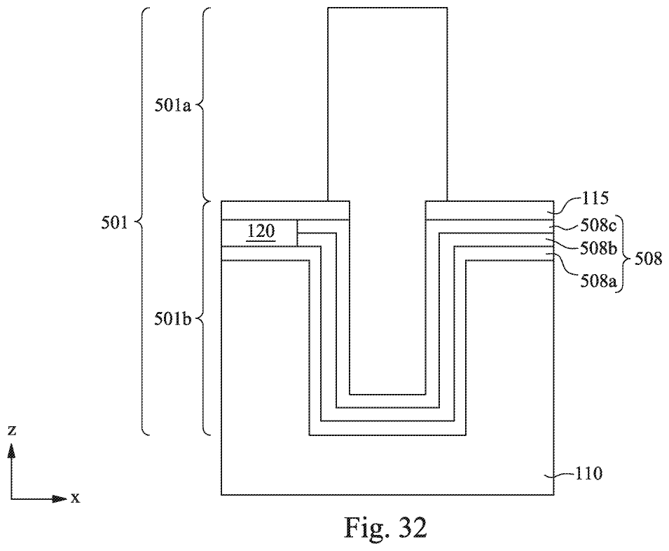

Referring now to FIG. 32, the method 300 at operation 318 patterns the semiconductor layer 114 to form a semiconductor feature 501. The semiconductor feature 501 may be formed by a patterning process that includes lithography and etching. In an embodiment, a lithography process is performed to form a patterned mask layer that covers portions of the semiconductor layer 114, and an etching process is performed using the patterned mask layer as an etch mask. The semiconductor feature 501 includes a first portion 501a over a second portion 501b. In the embodiment shown, the first portion 501a is wider than the second portion 501b, but in other embodiments, the first portion 501a may be narrower than the second portion 501b. In the embodiment shown, since the first portion 501a is wider, it also lands on top surfaces of the first insulating layer 115.

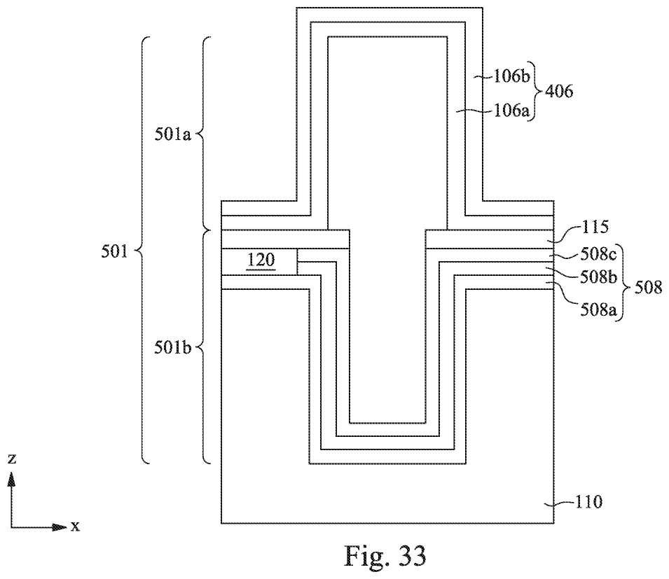

Referring now to FIG. 33, the method 300 at operation 320 forms a gate stack 406 over the semiconductor feature 501 by a suitable deposition process. The gate stack 406 includes a gate dielectric layer 106a and a gate electrode 106b over the gate dielectric layer 106a. The gate dielectric layer 106a may include a high-k dielectric material and the gate electrode 106b may include a suitable conductive material such as titanium nitride. The high-k dielectric material may include hafnium oxide, zirconium oxide, titanium oxide, silicon oxynitride, or other suitable dielectric materials. In some examples (not shown), the gate dielectric layer 106a and the gate electrode 106b each may include a number of sub-layers. Still referring to FIG. 33, the gate stack 406 may be conformally deposited over the semiconductor feature 501. As shown, the gate dielectric layer 106a lands on top and side surfaces of the first portion 501a of the semiconductor feature 501. The gate dielectric layer 106a also lands on top surfaces of the first insulating layer 115. Then, the gate electrode 106b lands on top and side surfaces of the gate dielectric layer 106a. Note that the first insulating layer 115 isolates the gate stack 406 from the capacitor structure 508.

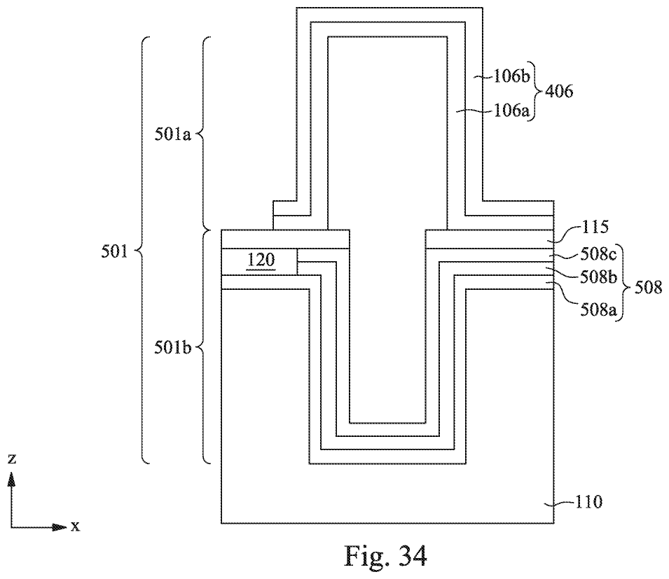

Referring now to FIG. 34, the method 300 at operation 322 etches through the gate stack 406 to expose a portion of the first insulating layer 115. Note that the exposed portion of the first insulating layer 115 is directly above the remaining portion of the second dielectric layer 120 directly on the electrode 508a of the capacitor structure 508.

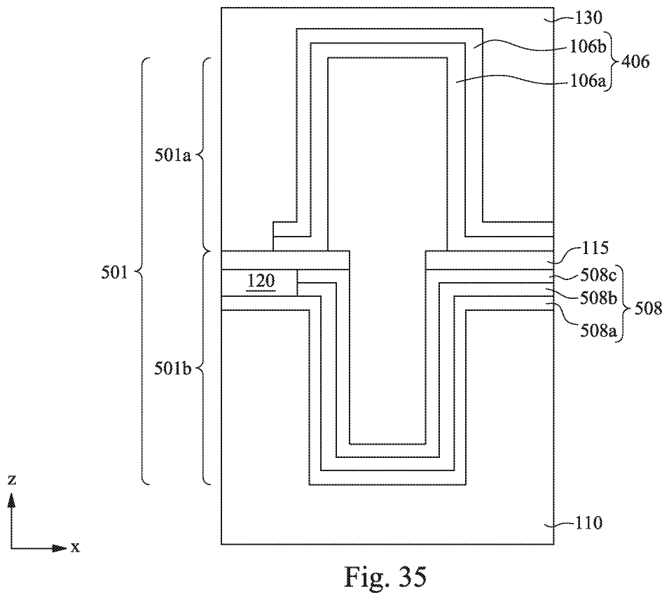

Referring now to FIG. 35, the method 300 at operation 324 forms a third dielectric layer 130 over the exposed portion of the first insulating layer 115 and over the gate stack 406 by a suitable deposition process. The third dielectric layer 130 may include similar materials as the dielectric layers 110 and 120. The third dielectric layer 130 directly contacts the gate stack 406 (including the gate dielectric layer 106a and the gate electrode 106b) and directly contacts top surfaces of the insulating layer 115. As shown, the third dielectric layer 130 surrounds and embeds the gate stack 406 and the first portion 501a of the semiconductor feature 501.

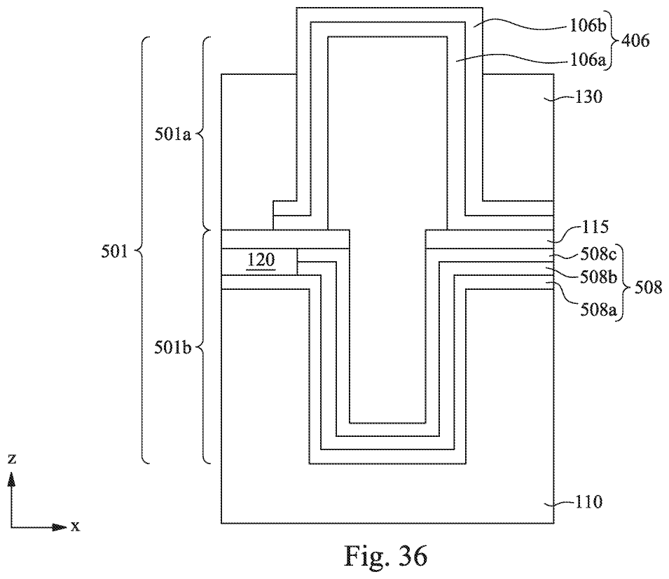

Referring now to FIG. 36, the method 300 at operation 326 performs a pull-back etch to the third dielectric layer 130. The pull-back etch exposes a top portion of the gate stack 406. The third dielectric layer 130 now surrounds and embeds a lower portion of the gate stack 406 (which later becomes the gate structure 506.)

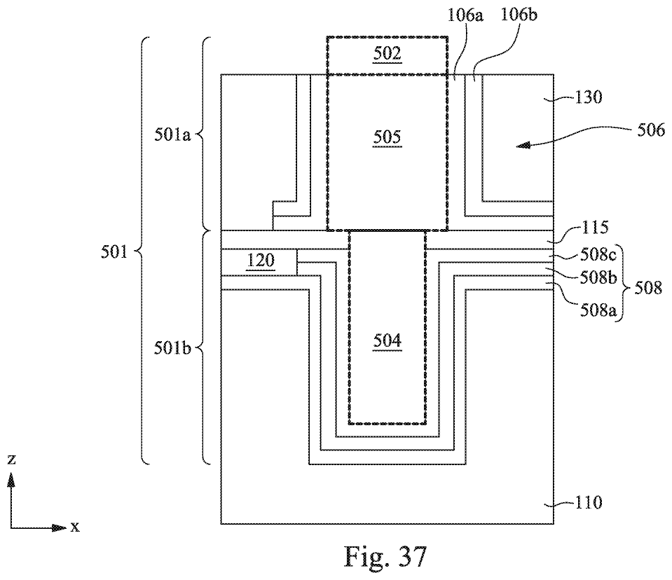

Referring now to FIG. 37, the method 300 at operation 328 etches the top portion of the gate stack 406 to expose a top portion of the first portion 501a of the semiconductor feature 501. Specifically, with respect to the semiconductor feature 501, a top portion of the first portion 501a is exposed while a bottom portion of the first portion 501a and the second portion 501b remain covered. The third dielectric layer 130 may act as an etch stop and etch mask when etching the top portion of the gate stack 406. The remaining portions of the gate stack 406 forms a gate structure 506. As described previously in FIGS. 20A-20B, the semiconductor feature 501 functions as a transistor 501 and includes portions that correspond to source, drain, and channel. After forming the gate structure 506, the source, drain, and channel portions of the semiconductor feature 501 are defined. For example, the semiconductor feature 501 includes a first S/D feature 502 that corresponds to the drain (or source) of the semiconductor feature 501. The semiconductor feature 501 includes a second S/D feature 504 that corresponds to the source (or drain) of the semiconductor feature 501. And the semiconductor feature 501 includes a channel 505 vertically between the first and second S/D features 502 and 504 that corresponds to the channel of the semiconductor feature 501. As shown in FIG. 37, the gate structure 506 horizontally wraps around the channel 505. The channel 505 is a vertical channel, with source and drain portions above and/or below the channel 505. The first S/D feature 502 corresponds to a top portion of the first portion 501a of the semiconductor feature 501, the channel 505 corresponds to a bottom portion of the first portion 501a of the semiconductor feature 501, and the second S/D feature 504 corresponds the second portion 501b of the semiconductor feature 501. In the embodiment shown, the channel 505 and the first S/D feature 502 have substantially the same width in the x direction because they are formed in a same patterning step, and each of the channel 505 and the first S/D feature 502 has a greater width in the x direction than the second S/D feature 504.

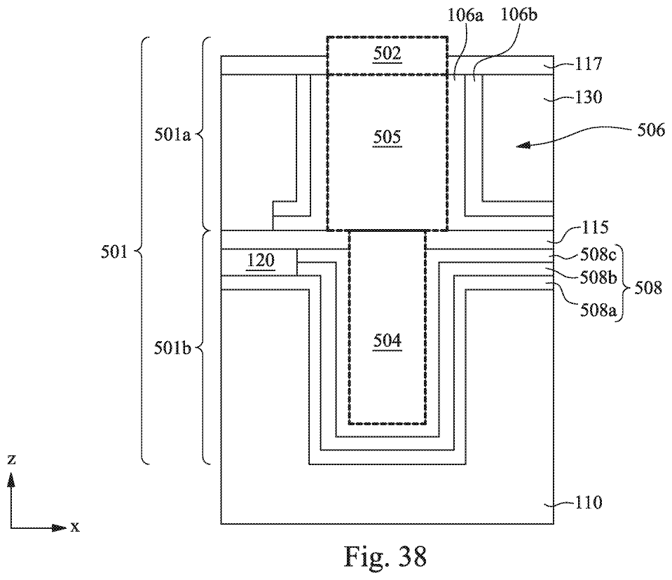

Referring now to FIG. 38, the method 300 at operation 330 forms a second insulating layer 117 over the gate structure 506 and over the third dielectric layer 130. The second insulating layer 117 may be of similar materials as the first insulating layer 115. The second insulating layer 117 may be formed by a directional deposition process such that the second insulating layer 117 is formed only (or substantially) on top surfaces of the gate structure 506, the third dielectric layer 130, and the first S/D feature 502. Then, an etching process may be performed by etching away portions of the second insulating layer 117 on the top surface of the first S/D feature 502. As a result, the second insulating layer 117 is formed as shown, on top surfaces of the gate structure 506, the third dielectric layer 130, and partially on side surfaces of the first S/D feature 502. After the formation of the second insulating layer 117, a top portion of the first S/D feature 502 remain exposed. The second insulating layer 117 may be an etch stop layer that includes silicon nitride. In an embodiment, the second insulating layer 117 includes a different dielectric material than that of the dielectric layers 110 and 120 for etchant selectivity.

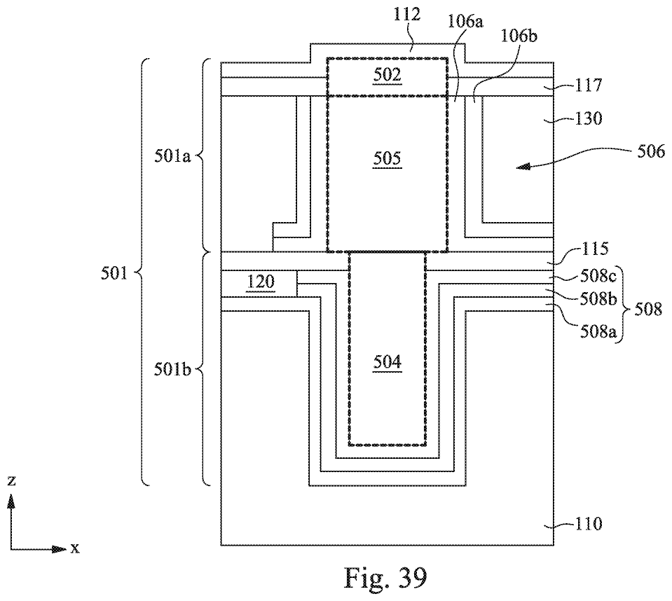

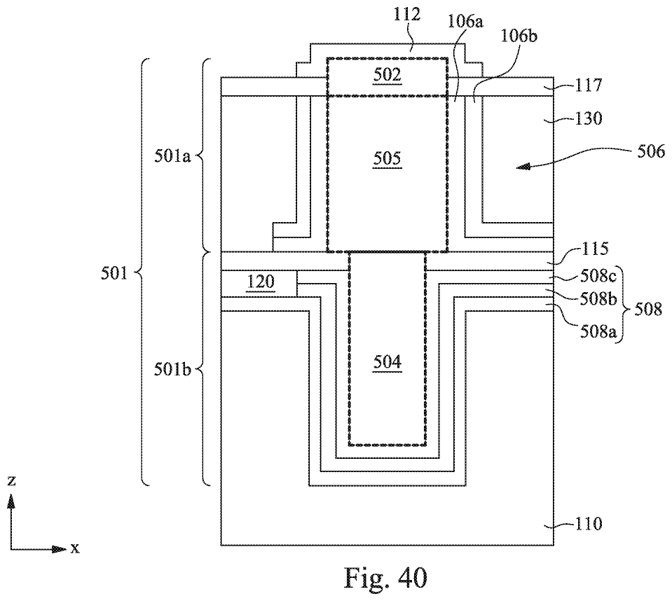

Referring now to FIGS. 39-40, the method 300 at operation 332 forms a conductive layer 112 over the second insulating layer 117 and over side and top surfaces of the exposed first S/D feature 502 (i.e., exposed side and top surfaces of the top portion of the first portion 501a of the semiconductor feature 501). The conductive layer 112 may include a suitable conductive material such as titanium nitride. The conductive layer 112 may be formed by a suitable deposition process (FIG. 39) followed by a patterning process (FIG. 40). The patterning process includes etching away side portions of the conductive layer 112 that land on the insulating layer 117. As shown, the conductive layer 112 may be directly above the gate structure 506 and the first S/D feature 502, but the conductive layer 112 may not be directly above the third dielectric layer 130 due to the patterning process.

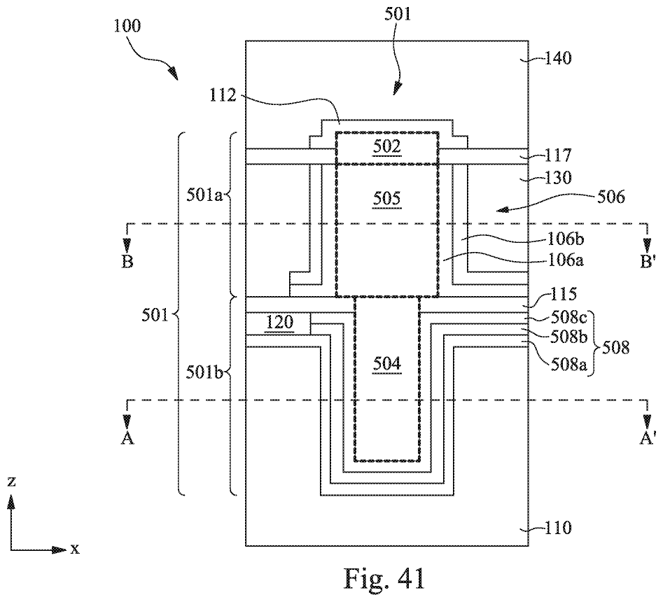

Referring now to FIG. 41, the method 300 at operation 334 forms a fourth dielectric layer 140 over the conductive layer 112 and over the second insulating layer 117 by a suitable deposition process. The fourth dielectric layer 140 may be of similar materials as the first, second, and third dielectric layer 110, 120, and 130. The fourth dielectric layer 140 directly contacts the conductive layer 112 and directly contacts top surfaces of the second insulating layer 117. The method 300 now forms a memory device 100 having a transistor 501 and a capacitor 508 below the transistor 501. As shown, the first and second insulating layers 115 and 117 separates various dielectric layers 110, 120, 130, and 140 that correspond to various levels of ILD layers. Further, the first insulating layer 115 separates the capacitor structure 508 from the gate structure 506, and the second insulating layer 117 separates the gate structure 506 from the conductive layer 112. To tune for higher capacitance, the height of the second S/D feature 504 along the z direction may be greater than the height of the channel 505 along the z direction (as shown). In a different embodiment, to tune for lower capacitance, the height of the second S/D feature 504 along the z direction may be smaller than the height of the channel 505 along the z direction. In other words, the height dimensions and ratio between the second S/D feature 504 and the channel 505 may be adjusted to meet low leakage current and high capacitance density goals.

FIG. 41 includes a line A-A′ across the second S/D feature 504 and a line B-B′ across the channel 505. FIGS. 42A-1, 42A-2, and 42A-3 illustrate top views of the memory device 100 in FIG. 41, cut along the lines A-A′, according to different embodiments of the present disclosure. FIGS. 42B-1, 42B-2, and 42B-3 illustrate top views of the memory device 100 in FIG. 41, cut along the lines B-B′, according to different embodiments of the present disclosure.

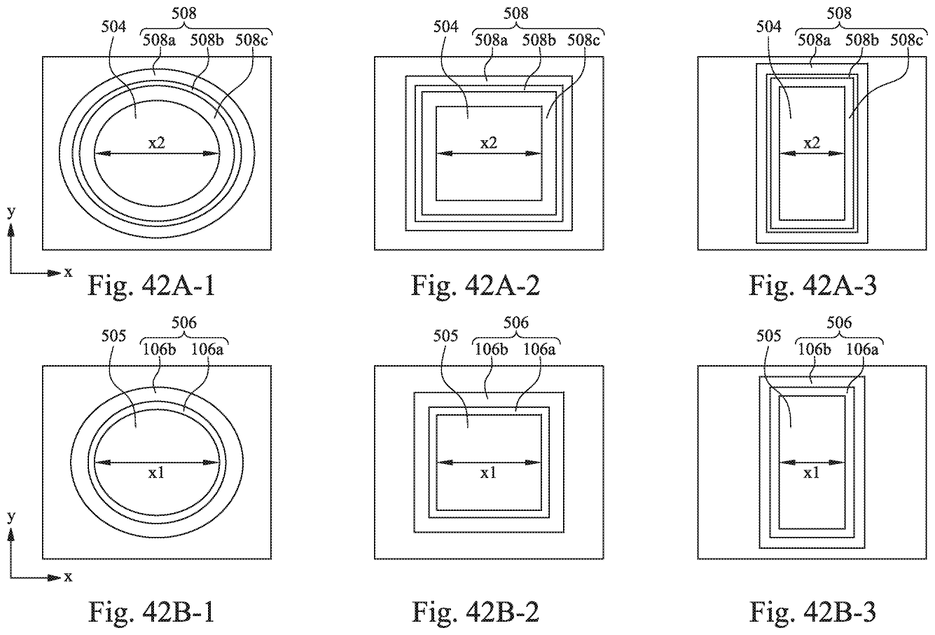

Referring now to FIGS. 42A-1, 42A-2, and 42A-3, the second S/D feature 504 may be fully wrapped around by the capacitor structure 508 in the x-y plane. The capacitor structure 508 includes the electrode 508c that directly contacts and fully wraps around the second S/D feature 504. The capacitor structure 508 includes the insulator 508b that directly contacts and fully wraps around the electrode 508c. The capacitor structure 508 further includes the electrode 508a that directly contacts and fully wraps around the insulator 508b. Although not shown, the capacitor structure 508 may include additional interleaved metal and insulator layers between the electrodes 508a and 508c. In an embodiment, the second S/D feature 504 has a circular shape in the x-y plane (see FIG. 42A-1). In another embodiment, the second S/D feature 504 has a square shape in the x-y plane (see FIG. 42A-2). In another embodiment, the second S/D feature 504 has a rectangular shape in the x-y plane (see FIG. 42A-3).

Referring now to FIGS. 42B-1, 42B-2, and 42B-3, the channel 505 may be fully wrapped around by the gate structure 506 in the x-y plane. The gate structure 506 includes the gate dielectric layer 106a that directly contacts and fully wraps around the channel 505. The gate structure 506 further includes the gate electrode 106b that directly contacts and fully wraps around the gate dielectric layer 106a. In an embodiment, the channel 505 has a circular shape in the x-y plane (see FIG. 42B-1). In another embodiment, the channel 505 has a square shape in the x-y plane (see FIG. 42B-2). In another embodiment, the channel 505 has a rectangular shape in the x-y plane (see FIG. 42B-3).

Each of the FIGS. 42A-1, 42A-2, and 42A-3 shows a width x2 of the respective second S/D features 504. Each of the FIGS. 42B-1, 42B-2, and 42B-3 shows a width x1 of the respective channels 505. In the present embodiment, for each corresponding pair of channel 505 and second S/D feature 504, the width x1 is greater than the width x2 (e.g., x1 in FIG. 42B-1 is greater than x2 in FIG. 42A-1). In other embodiments, for each corresponding pair of channel 505 and second S/D feature 504, the width x1 is smaller than the width x2 (e.g., x1 in FIG. 42B-1 is smaller than x2 in FIG. 42A-1). In either case, this is made possible because the channel 505 and the second S/D feature 504 may be formed of different widths as described with respect to FIG. 32 (i.e., first portion 501a has different width than second portion 501b of the semiconductor feature 501). This variation in width is different from what has been described previously with respect to FIGS. 15A-1, 15A-2, 15A-3, 15B-1, 15-B-2, and 15-B-3, and this variation may provide additional tuning window for varying capacitance.

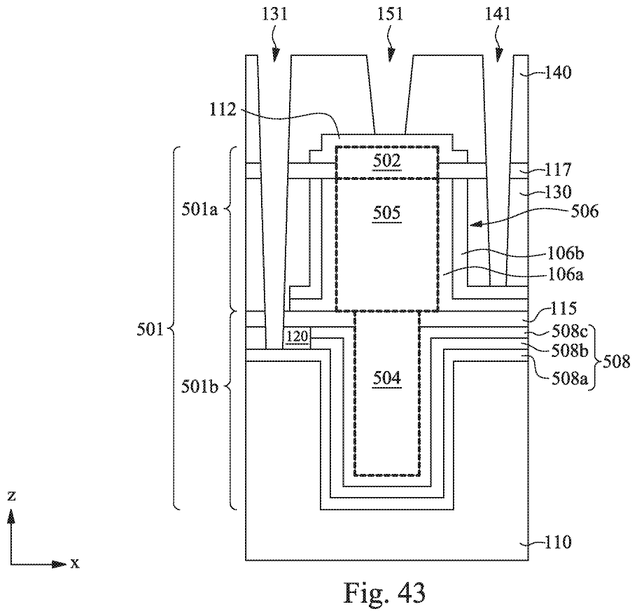

Referring now to FIG. 43, the method 300 at operation 336 forms a first via trench 131 through the fourth dielectric layer 140, the second insulating layer 117, the third dielectric layer 130, and the first insulating layer 115. In the embodiment shown, the first via trench 131 also forms through the second dielectric layer 120. The first via trench 131 exposes a metal layer (i.e., electrode 508a) of the capacitor structure 508. The exposed portion of the electrode 508a may be part of the opening 223 described in FIG. 26. The first via trench 131 does not expose the electrode 508c of the capacitor structure 508 due to the second dielectric layer 120 providing isolation. The fourth dielectric layer 140, the second insulating layer 117, the third dielectric layer 130, the first insulating layer 115, and the second dielectric layer 120 may be etched in a same or separate etching process when forming the first via trench 131. In one embodiment, the first via trench 131 is separately etched using different etching parameters when etching the dielectric layers 140, 130, and 120 versus the insulating layers 117 and 115.

Still referring to FIG. 43, the method 300 at operation 338 forms a second via trench 141 through the fourth dielectric layer 140, the second insulating layer 117, and the third dielectric layer 130. The second via trench 141 exposes the gate structure 506. The exposed portion of the gate structure 506 is a horizontal portion of the gate structure 506 that is directly on and above the first insulating layer 115. Specifically, the second via trench 141 exposes a horizontal surface of the gate electrode 106b. The trench depth of the second via trench 141 is not as deep as the first via trench 131. The fourth dielectric layer 140, the second insulating layer 117, and the third dielectric layer 130 may be etched in a same or separate etching process when forming the second via trench 141. In one embodiment, the second via trench 141 is separately etched using different etching parameters when etching the dielectric layers 140 and 130 versus the insulating layer 117.

Still referring to FIG. 43, the method 300 at operation 340 forms a third via trench 151 through the fourth dielectric layer 140. The third via trench 151 exposes a top surface of the conductive layer 112. As shown, the trench depth of the third via trench 151 may be much shallower than the first via trench 131 and the second via trench 141. This is because the third via trench 151 does not penetrate through the insulating layers 115 and/or 117. To prevent over-etching and damaging the conductive layer 112, the third via trench 151 may be separately formed from the first and second via trenches 131 and 141. For example, the first and second via trenches 131 and 141 may be formed together in a first patterning process that includes lithography and etching, then the third via trench 151 is formed in a second patterning process that includes lithography and etching. In another embodiment, the first and second via trenches 131 and 141 may be partially formed in a first patterning process by etching these trenches to a first depth. Then in a second patterning process, the first, second, and third via trenches 131, 141, and 151 are formed together by further etching the first and second via trenches 131 and 141 to a second depth exposing the electrode 508a of the capacitor structure 508 and the gate structure 506 and etching the third via trench 151 exposing the conductive layer 112. In further embodiments, the first, second, and third via trenches 131, 141, and 151 may all be separately formed in separate patterning processes.

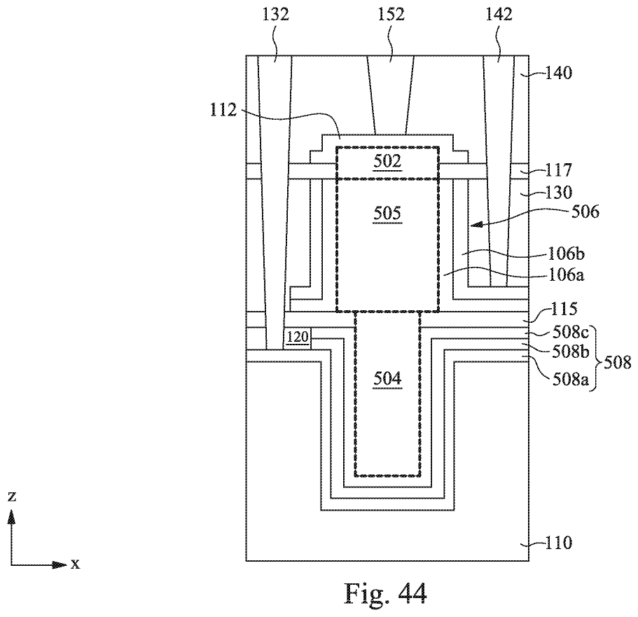

Referring now to FIG. 44, the method 300 at operation 342 forms a first via 132, a second via 142, and a third via 152 in the first, second, and third via trenches 131, 141, and 151, respectively. These vias may be formed by any suitable deposition techniques such as PVD or CVD to deposit a metal material in the first, second, and third via trenches 131, 141, and 151. Then, a CMP process may be performed to remove any overfill of the metal material and level the memory device 100, thereby forming the first, second, and third vias 132, 142, and 152. The metal material of the first, second, and third vias 132, 142, and 152 may include titanium (Ti), ruthenium (Ru), copper (Cu), nickel (Ni), cobalt (Co), tungsten (W), tantalum (Ta), molybdenum (Mo), or a combination thereof.

Still referring to FIG. 44, the first via 132 directly lands on the capacitor structure 508, and specifically a first electrode (e.g., electrode 508a) of the capacitor structure. A second electrode (e.g., electrode 508c) of the capacitor structure is electrically connected to the second S/D feature 504 of the semiconductor feature 501. Specifically, the electrode 508a directly contacts the first via 132, and the electrode 508c directly contacts the second S/D feature 504. The first via 132 corresponds to a ground line via that electrically routes to a ground line of the memory device 100. The second via 142 directly lands on the gate structure 506, which wraps around the channel 505 of the semiconductor feature 501. The second via 142 corresponds to a word line via that electrically routes to a word line of the memory device 100. The third via 152 directly lands on the conductive layer 112, which is electrically connected to the first S/D feature 502 of the semiconductor feature 501. The third via 152 corresponds to a bit line via that electrically routes to a bit line of the memory device 100.

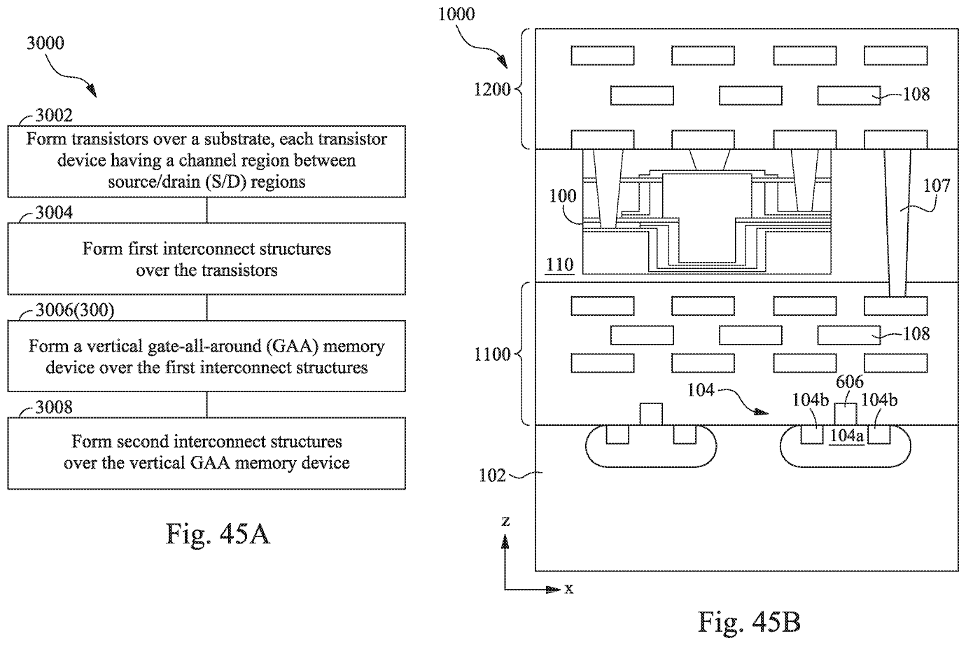

FIG. 45A illustrates a flow chart of a method 3000 to form an integrated circuit 1000 that includes the memory device 100 in FIG. 20B (or FIG. 44), according to an embodiment of the present disclosure. FIG. 45B illustrates the integrated circuit 1000 formed by the method 3000 of FIG. 45A. Referring to FIGS. 45A and 45B, the method 3000 at operation 3002 forms transistor devices 104 over a substrate 102. The transistor devices 104 may be different from the memory device 100 described previously. In an embodiment, the transistor devices 104 are logic devices. Each of the transistor devices 104 includes a channel region 104a between source/drain (S/D) regions 104b. The channel region 104a and S/D regions 104b may be part of an active region over the substrate 102. Each transistor device 104 includes a gate 606 over the channel region 104a. The transistor devices 104 may be planar devices (as shown) or they could be fin field-effect-transistors (FETs) or gate-all-around (GAA) FETs.

Referring now to operation 3004, the method 3000 forms a first interconnect structure 1100 over the transistor devices. The first interconnect structure 1100 includes metal contacts such as S/D contacts and gate contacts (not explicitly shown) that land on the S/D region 104b and the gate 606, vias such as S/D vias and gate vias (not explicitly shown) that land on the metal contacts, and metal lines 108 that land on and electrically connect to the various metal contacts and vias. The various metal contacts, vias, and metal lines of the interconnect structure 1100 may be surrounded by or embedded in an interlayer dielectric layer (ILD). Referring now to operation 3006, the method 3000 forms a vertical GAA memory device 100 over the first interconnect structure 1100. The vertical GAA memory device 100 may be formed by the method 300 as described previously. In the embodiment shown, the memory device 100 is formed over and/or embedded in a dielectric layer 110 above the first interconnect structure 1100. The dielectric layer 110 may also surround the memory device 100 and embed other features such as a through-via 107. Referring now to operation 3008, the method 3000 forms a second interconnect structure 1200 over the vertical GAA memory device 100. The second interconnect structure 1200 includes various metal lines 108 that electrically connect to the memory device 100. For example, some of these metal lines 108 may land on the first, second, and third vias 132, 142, and 152. These metal lines 108 are then connected to higher level metal lines 108 for further routing. Some of the metal lines 108 in the second interconnect structure 1200 may land on through-vias 107, which bypasses the memory device 100 to land on a metal line 108 in the first interconnect structure 1100.

As shown and described with respect to FIGS. 45A and 45B, the memory device 100 of FIG. 20B (or FIG. 44) may be incorporated and sandwiched between metal lines 108. These metal lines 108, whether in the first or second interconnect structure 1100 or 1200, are frontside metal lines formed over transistor devices 104. In some embodiments, because of the increased device density benefits of the memory device 100, a vertical spacing between the metal lines 108 that sandwich the memory device 100 is about the same as a vertical spacing between metal lines 108 that do not sandwich any memory device 100. In other embodiments, the spacing between the metal lines 108 that sandwich the memory device 100 is larger than the spacing between metal lines 108 that do not sandwich any memory devices 100. Note that multiple memory devices 100 may be configured between various metal lines 108. In an embodiment, the formed integrated circuit 1000 may include multiple vertical GAA transistors for memory devices 100 and multiple horizontal GAA transistors for logic devices (i.e., transistor devices 104). That is, the memory devices 100 have vertical channels horizontally wrapped by gate electrodes, and the logic devices (i.e., transistor devices 104) have horizontal channels vertically wrapped by gate electrodes.

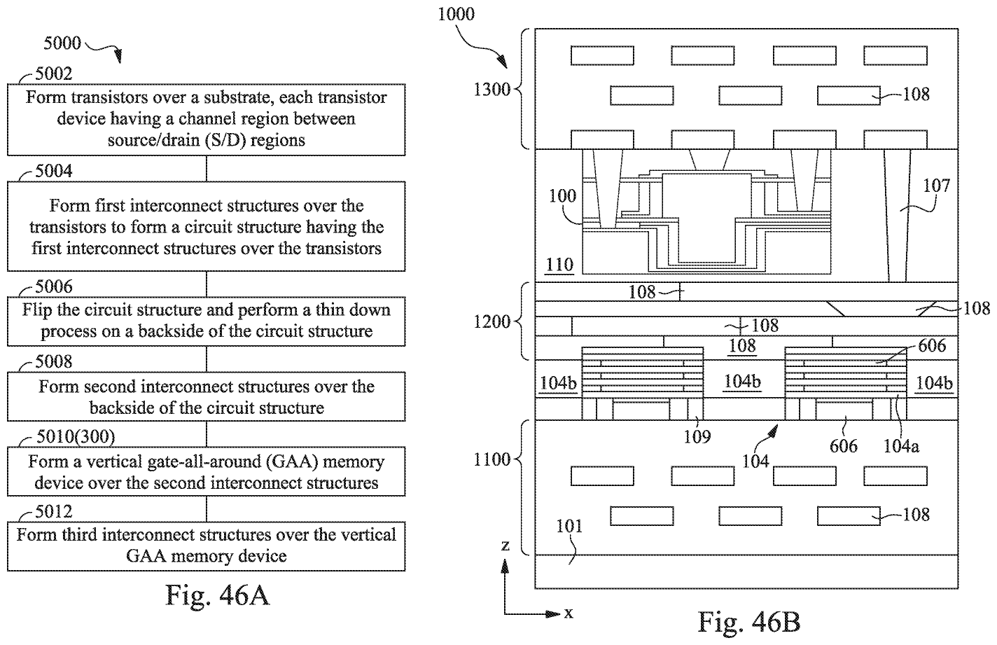

FIG. 46A illustrates a flow chart of a method 5000 to form an integrated circuit 1000 that includes the memory device 100 in FIG. 20B (or FIG. 44), according to another embodiment of the present disclosure. FIG. 46B illustrates the integrated circuit 1000 formed by the method 5000 of FIG. 46A. Referring to FIGS. 46A and 46B, the method 5000 at operation 5002 forms transistor devices 104 over a substrate (the substrate is not shown). The transistor devices 104 may be different from the memory device 100 described previously. In an embodiment, the transistor devices 104 are logic devices. Each of the transistor devices 104 includes a channel region 104a between source/drain (S/D) regions 104b. In the embodiment shown, the channel region 104a may include a stack of multiple channel layers that connect between S/D regions 104b. Each transistor device 104 includes a gate 606 over the channel region 104a. However, as shown in FIG. 19B, the gate 606 is disposed under the channel region 104a after flipping the circuit structure in operation 4006. The gate 606 may include gate dielectric and gate electrodes and the gate 606 may have portions that vertically wrap around multiple channel layers. The gate 606 may include gate dielectric and gate electrodes that vertically wrap around multiple channel layers. Each transistor devices 104 may include spacers 109 such as gate spacers, inner spacers, or other insulating spacers that insulate between channel layers, gate structures, and other relevant surrounding features. In some embodiments, the spacers 109 includes a dielectric material that includes silicon, oxygen, carbon, nitrogen, other suitable material, or combinations thereof (for example, silicon oxide, silicon nitride, silicon oxynitride, silicon carbide, or silicon oxycarbonitride). In some embodiments, the spacer layer includes a low-k dielectric material. The transistor devices 104 may be GAA FETs as shown, or they could be planar devices or fin FET devices.

Referring now to operation 5004, the method 5000 forms a first interconnect structure 1100 over the transistor devices 104, thereby forming a circuit structure having the first interconnect structure 1100 and the transistor devices 104. Note that FIG. 46B shows the first interconnect structure 1100 under the transistor devices 104. This is because the circuit structure is flipped upside down in a later fabrication step. The first interconnect structure 1100 includes metal contacts such as S/D contacts and gate contacts (not explicitly shown) that land on the S/D region 104b and the gate 606, vias such as S/D vias and gate vias (not explicitly shown) that land on the metal contacts, and metal lines 108 that land on and electrically connect to the various metal contacts and vias. The various metal contacts, vias, and metal lines of the interconnect structure 1100 may be surrounded by or embedded in an interlayer dielectric layer (ILD). Referring now to operation 5006, the method 5000 flips the circuit structure having the first interconnect structure 1100 and the transistor devices 104 and performs a thin down process on a backside of the circuit structure. The operation 5006 may include forming a bonding substrate 101 over the interconnect structure 1100 for structural integrity, then flipping the whole workpiece and performing a thin down process to remove portions of the circuit structure where the transistor devices 104 are first formed over. Referring now to operation 5008, the method 5000 forms a second interconnect structure 1200 over a backside of the circuit structure (since it is now flipped). The second interconnect structure 1200 includes various metal lines 108 that electrically connect to the transistor device 104. For example, some of these metal lines 108 may include backside vias that land from the backside onto the S/D regions 104b of the transistor devices 104, and backside conductive lines that land on the backside vias. These backside conductive lines may also be referred to as backside power rails for routing power from a backside of the transistor devices 104. These metal lines 108 are then connected to metal lines 108 in the third interconnect structure for further routing. Referring now to operation 5010, the method 5000 forms a vertical GAA memory device 100 over the second interconnect structure 1200. The vertical GAA memory device 100 may be formed by the method 300 as described previously. In the embodiment shown, the memory device 100 is formed over a dielectric layer 110 above the second interconnect structure 1200. The dielectric layer 110 may also surround the memory device 100 and embed other features such as a through-via 107. Referring now to operation 5012, the method 5000 forms a third interconnect structure 1300 over the vertical GAA memory device 100. As such, the vertical GAA memory device 100 is formed between backside power rails in the second interconnect structure 1200 and the metal routings in the third interconnect structure 1300. The third interconnect structure 1300 includes various metal lines 108 that electrically connect to the memory device 100. For example, some of these metal lines 108 may land on the first, second, and third vias 132, 142, and 152. These metal lines 108 are then connected to higher level metal lines 108 for further routing. Some of the metal lines 108 in the third interconnect structure 1300 may land on through-vias 107, which bypasses the memory device 100 to land on a metal line 108 in the second interconnect structure 1200.

As shown and described with respect to FIGS. 46A and 46B, the memory device 100 of FIG. 20B (or FIG. 44) may be incorporated and sandwiched between metal lines 108. These metal lines 108 are backside metal lines formed on a backside of the transistor devices 104. In some embodiments, because of the increased device density benefits of the memory device 100, a vertical spacing between the metal lines 108 that sandwich the memory device 100 is about the same as a vertical spacing between metal lines 108 that do not sandwich any memory device 100. In other embodiments, the spacing between the metal lines 108 that sandwich the memory device 100 is larger than the spacing between metal lines 108 that do not sandwich any memory devices 100. Note that multiple memory devices 100 may be configured between various metal lines 108. In an embodiment, the formed integrated circuit 1000 may include multiple vertical GAA transistors for memory devices 100 and multiple horizontal GAA transistors for logic devices (i.e., transistor devices 104). That is, the memory devices 100 have vertical channels horizontally wrapped by gate electrodes, and the logic devices (i.e., transistor devices 104) have horizontal channels vertically wrapped by gate electrodes.

Although not limiting, the present disclosure offers advantages for memory devices having a transistor and a capacitor. One example advantage is vertically stacking the transistor and capacitor of the memory device to reduce passive device area and increase device density. The capacitor directly contacts the source and/or drain regions of the transistor for direct coupling. Further, the present disclosure allows the capacitor to be directly above or below the transistor. Even further, the present disclosure contemplates different dimensions of the transistor and capacitor to adjust capacitance. Another example advantage is incorporating the vertically stacked memory device in an IC circuit such that the IC circuit may include vertical GAA transistors for memory devices and horizontal GAA transistors for logic devices. Further, multiple of the vertically stacked memory devices may be formed in a frontside interconnect structure or a backside interconnect structure for easy integration.

One aspect of the present disclosure pertains to a memory device. The memory device includes a semiconductor feature made of a compound semiconductor material. The semiconductor features includes a first portion as a first source/drain (S/D) feature, a second portion as a channel, and a third portion as a second S/D feature. The first portion is above the second portion and the second portion is above the third portion, and the second portion vertically extends from the first portion to the third portion. The memory device includes a gate structure horizontally wrapping around the second portion and a capacitor structure in direct contact with and wrapping around the semiconductor feature.

In an embodiment, the semiconductor feature has an amorphous or polycrystalline structure. In an embodiment, the semiconductor feature includes indium gallium zinc oxide (IGZO).

In an embodiment, the capacitor structure has a first electrode, a second electrode, and an insulator layer between the first and the second electrodes. The first electrode directly lands on a horizontal and a vertical surface of the semiconductor feature. The second electrode is electrically connected to a ground line.

In a further embodiment, the gate structure is electrically connected to a word line. The capacitor structure wraps around the third portion of the semiconductor feature and the first portion of the semiconductor feature is electrically connected to a bit line.

In a further embodiment, the gate structure is electrically connected to a word line, the capacitor structure wraps around the first portion of the semiconductor feature and the third portion of the semiconductor feature is electrically connected to a bit line.

In an embodiment, the memory device further includes a dielectric layer between the gate structure and the capacitor structure, the dielectric layer isolates the gate structure from the capacitor structure and is on sidewalls of the semiconductor feature. In a further embodiment, the dielectric layer is a first dielectric layer, and the memory device further includes a second dielectric layer above the first dielectric layer; and a conductive layer over the second dielectric layer and in direct contact with the semiconductor feature. The second dielectric layer is between the gate structure and the conductive layer, and the second dielectric layer isolates the gate structure from the conductive layer and is on sidewalls of the semiconductor feature.

In an embodiment, the memory device further includes a conductive layer in direct contact with the semiconductor feature and on a opposite side of the capacitor structure. The gate structure is vertically between the conductive layer and the capacitor structure. The capacitor structure, the gate structure, and the conductive layer are each separated from each other. In a further embodiment, the memory device further includes a bit line via landing on the conductive layer, the bit line via electrically connected to a bit line, a ground via landing on the capacitor structure, the ground via electrically connected to a ground line, and a word line via landing on the gate structure, the word line via electrically connected to a word line.

Another aspect of the present disclosure pertains to a memory device. The memory device includes a conductive layer over a dielectric layer. The memory device includes a semiconductor feature made of a compound semiconductor material over the conductive layer, the semiconductor feature includes a first portion as a first source/drain (S/D) feature, a second portion as a channel, and a third portion as a second S/D feature. The first portion is above the second portion and the second portion is above the third portion, and the second portion vertically extends from the first portion to the third portion. The memory device includes a gate structure horizontally wrapping around the second portion of the semiconductor feature, a metal-insulator-metal (MIM) capacitor structure over the first portion of the semiconductor feature, the MIM capacitor structure directly contacts top and side surfaces of the first portion of the semiconductor feature. The memory device further includes an insulating layer between the gate structure and the MIM capacitor structure.

In an embodiment, the MIM capacitor structure has a first electrode and a second electrode, the first electrode is electrically connected to the first portion of the semiconductor feature, and the second electrode is electrically connected to a ground line. The gate structure is electrically connected to a word line. The third portion of the semiconductor feature is electrically connected to a bit line.

In an embodiment, the compound semiconductor material includes oxygen and at least two of the following three materials: indium, gallium, and zinc.

In an embodiment, the gate structure includes a gate dielectric layer wrapping around the second portion of the semiconductor feature and a gate electrode layer wrapping around the gate dielectric layer.

In an embodiment, the memory device further includes a first interlayer dielectric (ILD) layer over the conductive layer, wherein the gate structure is embedded in the first ILD layer, and a second ILD layer over the insulating layer, wherein the capacitor structure is embedded in the second ILD layer. The insulating layer separates the first ILD layer from the second ILD layer.

In a further embodiment, the memory device further includes a bit line via penetrating through the second ILD layer, the insulating layer, and the first ILD layer to land on the conductive layer; a ground via penetrating through the second ILD layer to land on the MIM capacitor structure; and a word line via penetrating through the second ILD layer, the insulating layer, and the first ILD layer to land on the gate structure.

In an embodiment, the first portion has a first width along a first direction, the second portion has a second width along the first direction, and the third portion has a third width along the first direction. The first width and the second width is substantially the same, and the third width is greater than the second width.

Another aspect of the present disclosure pertains to a method. The method includes forming a conductive layer over a first dielectric layer; forming a semiconductor layer over the conductive layer; patterning the semiconductor layer to form a semiconductor feature having a first portion over a second portion, the second portion is wider than the first portion; forming a gate stack over the semiconductor feature; forming a second dielectric layer over the gate stack; etching through the second dielectric layer, the gate stack, and the second portion of the semiconductor feature to form a trench exposing a landing portion of the conductive layer; reforming the second dielectric layer by filling the trench with a dielectric material; performing a pull-back etch to the second dielectric layer, thereby exposing a top portion of the gate stack; etching the top portion of the gate stack to expose a top portion of the first portion of the semiconductor feature, where remaining portions of the gate stack form a gate structure horizontally wrapping around a vertical channel of the semiconductor feature; forming an insulating layer over the gate structure and the second dielectric layer; forming a metal-insulator-metal (MIM) capacitor structure over the insulating layer and over side and top surfaces of the exposed top portion of the first portion of the semiconductor feature; and forming a third dielectric layer over the MIM capacitor structure.

In an embodiment, the method further includes forming a first via through the third dielectric layer, the insulating layer, and the second dielectric layer, and the first via lands on the landing portion of the conductive layer; forming a second via through the third dielectric layer, the insulating layer, and the second dielectric layer, and the second via lands on the gate structure; and forming a third via through the third dielectric layer, and the third via lands on the MIM capacitor structure.

In an embodiment, the semiconductor layer includes indium gallium zinc oxide (IGZO).

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A memory device, comprising:
a semiconductor feature made of a compound semiconductor material and having a first portion as a first source/drain (S/D) feature, a second portion as a channel, and a third portion as a second S/D feature, wherein the first portion is above the second portion and the second portion is above the third portion, and the second portion vertically extends from the first portion to the third portion;
a gate structure horizontally wrapping around the second portion; and
a capacitor structure in direct contact with and wrapping around the semiconductor feature.

2. The memory device of claim 1, wherein the semiconductor feature has an amorphous or polycrystalline structure.

3. The memory device of claim 1, wherein the semiconductor feature includes indium gallium zinc oxide (IGZO).

4. The memory device of claim 1,
wherein the capacitor structure has a first electrode, a second electrode, and an insulator layer between the first and the second electrodes,
wherein the first electrode directly lands on a horizontal and a vertical surface of the semiconductor feature,
wherein the second electrode is electrically connected to a ground line.

5. The memory device of claim 4,
wherein the gate structure is electrically connected to a word line,
wherein the capacitor structure wraps around the third portion of the semiconductor feature and the first portion of the semiconductor feature is electrically connected to a bit line.

6. The memory device of claim 4,
wherein the gate structure is electrically connected to a word line,
wherein the capacitor structure wraps around the first portion of the semiconductor feature and the third portion of the semiconductor feature is electrically connected to a bit line.

7. The memory device of claim 1, further comprising:
a dielectric layer between the gate structure and the capacitor structure, the dielectric layer isolates the gate structure from the capacitor structure and is on sidewalls of the semiconductor feature.

8. The memory device of claim 7, wherein the dielectric layer is a first dielectric layer, further comprising:
a second dielectric layer above the first dielectric layer; and
a conductive layer over the second dielectric layer and in direct contact with the semiconductor feature,
wherein the second dielectric layer is between the gate structure and the conductive layer, and the second dielectric layer isolates the gate structure from the conductive layer and is on sidewalls of the semiconductor feature.

9. The memory device of claim 1, further comprising:
a conductive layer in direct contact with the semiconductor feature and on a opposite side of the capacitor structure,
wherein the gate structure is vertically between the conductive layer and the capacitor structure, wherein the capacitor structure, the gate structure, and the conductive layer are each separated from each other.

10. The memory device of claim 9, further comprising:
a bit line via landing on the conductive layer, the bit line via electrically connected to a bit line;
a ground via landing on the capacitor structure, the ground via electrically connected to a ground line; and
a word line via landing on the gate structure, the word line via electrically connected to a word line.

11. A memory device, comprising:
a conductive layer over a dielectric layer;
a semiconductor feature made of a compound semiconductor material over the conductive layer, the semiconductor feature includes a first portion as a first source/drain (S/D) feature, a second portion as a channel, and a third portion as a second S/D feature, wherein the first portion is above the second portion and the second portion is above the third portion, and the second portion vertically extends from the first portion to the third portion;
a gate structure horizontally wrapping around the second portion of the semiconductor feature;
a metal-insulator-metal (MIM) capacitor structure over the first portion of the semiconductor feature, wherein the MIM capacitor structure directly contacts top and side surfaces of the first portion of the semiconductor feature; and
an insulating layer between the gate structure and the MIM capacitor structure.

12. The memory device of claim 11,
wherein the MIM capacitor structure has a first electrode and a second electrode, the first electrode is electrically connected to the first portion of the semiconductor feature, and the second electrode is electrically connected to a ground line,
wherein the gate structure is electrically connected to a word line,
wherein the third portion of the semiconductor feature is electrically connected to a bit line.

13. The memory device of claim 11, wherein the compound semiconductor material includes oxygen and at least two of the following three materials: indium, gallium, and zinc.

14. The memory device of claim 11, wherein the gate structure includes a gate dielectric layer wrapping around the second portion of the semiconductor feature and a gate electrode layer wrapping around the gate dielectric layer.

15. The memory device of claim 11, further comprising:
a first interlayer dielectric (ILD) layer over the conductive layer, wherein the gate structure is embedded in the first ILD layer; and
a second ILD layer over the insulating layer, wherein the capacitor structure is embedded in the second ILD layer,
wherein the insulating layer separates the first ILD layer from the second ILD layer.

16. The memory device of claim 15, further comprising:
a bit line via penetrating through the second ILD layer, the insulating layer, and the first ILD layer to land on the conductive layer;
a ground via penetrating through the second ILD layer to land on the MIM capacitor structure; and
a word line via penetrating through the second ILD layer, the insulating layer, and the first ILD layer to land on the gate structure.

17. The memory device of claim 11,
wherein the first portion has a first width along a first direction, the second portion has a second width along the first direction, and the third portion has a third width along the first direction,
wherein the first width and the second width is substantially the same, and the third width is greater than the second width.

18. A method of forming a memory device, comprising:
forming a conductive layer over a first dielectric layer;
forming a semiconductor layer over the conductive layer;
patterning the semiconductor layer to form a semiconductor feature having a first portion over a second portion, wherein the second portion is wider than the first portion;
forming a gate stack over the semiconductor feature;
forming a second dielectric layer over the gate stack;
etching through the second dielectric layer, the gate stack, and the second portion of the semiconductor feature to form a trench exposing a landing portion of the conductive layer;
reforming the second dielectric layer by filling the trench with a dielectric material;
performing a pull-back etch to the second dielectric layer, thereby exposing a top portion of the gate stack;
etching the top portion of the gate stack to expose a top portion of the first portion of the semiconductor feature, wherein remaining portions of the gate stack form a gate structure horizontally wrapping around a vertical channel of the semiconductor feature;
forming an insulating layer over the gate structure and the second dielectric layer;
forming a metal-insulator-metal (MIM) capacitor structure over the insulating layer and over side and top surfaces of the exposed top portion of the first portion of the semiconductor feature; and
forming a third dielectric layer over the MIM capacitor structure.

19. The method of claim 18, further comprising:
forming a first via through the third dielectric layer, the insulating layer, and the second dielectric layer, and the first via lands on the landing portion of the conductive layer;
forming a second via through the third dielectric layer, the insulating layer, and the second dielectric layer, and the second via lands on the gate structure; and
forming a third via through the third dielectric layer, and the third via lands on the MIM capacitor structure.

20. The method of claim 18, wherein the semiconductor layer includes indium gallium zinc oxide (IGZO).
